(19) United States
(12) Patent Application Publication
(10) Pub. No.: US 2026/0323886 A1
(43) Pub. Date: Oct. 15, 2026

(54) CRYOGENIC COOLING SYSTEMS AND METHODS

(71) Applicant: Nvidia Corporation, Santa Clara, CA (US)

(72) Inventors: John Franz, Tomball, TX (US); Elad Mentovich, Tel Aviv (IL)

(21) Appl. No.: 19/175,796

(22) Filed: Apr. 10, 2025

(51) Int. Cl. H05K 7/20

(52) U.S. Cl. CPC H05K 7/20836; H05K 7/20272; H05K 7/20372; H05K 7/20772

(57) ABSTRACT

A coolant distribution unit (CDU) and a cryogenic cooling unit (CCU) may cool heat-generating components in hardware. The CDU and CCU may be selectively activated to cool the heat-generating components during high-performance tasks. The CCU may be activated in response to a high amount of heat generation, GPU utilization, or power consumption. The CCU and CDU may have separate cooling loops which cover nonoverlapping portions of hardware.

### BACKGROUND

In cooling environments, water-based coolant is often used to dissipate heat from heat-generating components. However, improving certain performance metrics, such as Time to First Token (TTFT) and token output per second (token/s), requires a relatively high workload from computing components. Increasing workloads will also increase the thermal energy generated by the computing components. Although water-based coolant may cool the computing components to some degree, the cooling action provided by the water-based coolant may not be quick enough to meaningfully improve the components'performance with regard to certain metrics like TTFT and token/s.

### BRIEF DESCRIPTION OF THE DRAWINGS

Various embodiments in accordance with the present disclosure will be described with reference to the drawings, in which:

FIGS. 1A-1B illustrate a system for operating a coolant distribution unit (CDU) and a cryogenic cooling unit (CCU) to dissipate heat from hardware, according to example embodiments;

FIG. 2A illustrates an apparatus for distributing water-based coolant and cryogenic fluid to one or more hardware, according to example embodiments;

FIG. 2B illustrates cooling loops to distribute water-based coolant and cryogenic fluid to a hardware component, according to example embodiments;

FIG. 2C illustrates a CDU and CCU connecting to hardware via one or more fluid connections and facility connections, according to example embodiments;

FIG. 3A illustrates a system for activating a CCU based on hardware performance metrics, according to example embodiments;

FIG. 3B illustrates a system for activating a CCU based on temperature data, according to example embodiments;

FIG. 3C illustrates a system for adjusting the flow of a CCU based on a user-requested adjustment, according to example embodiments;

FIG. 3D illustrates time to first token (TTFT) and inter-token latency (ITL), according to example embodiments;

FIGS. 4A-4B illustrate a system for activating a CCU responsive to a temperature change, according to example embodiments;

FIG. 5A illustrates a process for activating a CDU and CCU during different time periods, according to example embodiments;

FIG. 5B illustrates a process for adjusting the flow of a CDU and CCU responsive to a user-requested adjustment, according to example embodiments;

FIG. 5C illustrates a process for activating a CCU based on a prediction, according to example embodiments;

FIG. 6 illustrates components of a distributed system that may be utilized in a data center, according to one or more embodiments;

FIG. 7 illustrates an example data center system, according to one or more embodiments;

FIG. 8 illustrates an example computing environment, according to one or more embodiments;

FIG. 9 illustrates a computer system, according to one or more embodiments;

FIG. 10 illustrates a computing system, according to one or more embodiments;

FIG. 11 illustrates an optoelectronic component, according to one or more embodiments;

FIG. 12 illustrates an optoelectronic component according to one or more embodiments;

FIG. 13 illustrates an optoelectronic component with a substrate and integrated circuit according to one or more embodiments;

FIG. 14 illustrates an optoelectronic component in a transceiver according to one or more embodiments; and

FIG. 15 illustrates a networking device according to one or more embodiments.

### DETAILED DESCRIPTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

In some cooling environments, water-based cooling loops are used to dissipate heat from heat-generating components such as CPUs and GPUs. The water-based coolant temperature range may be optimized for complementary metal oxide semiconductor (CMOS) based hardware, but it may also support the needs of surrounding copper or super conducting materials on steady-state processing demands. The superconducting signal traces in the circuit board may shorten the duration to generate the first token by using a cryogenic fluid loop, which provides a colder cooling environment than the water-based coolant. The cryogenic fluid loop is selectively used i.e. not used all the time but only when needed. In example embodiments, the cryogenic cooling unit can be used to accelerate weak links in the data center. The water-based coolant is used for subsequent generations of tokens and other activities, making the two cooling systems complementary. As the cooling loops dissipate heat, the integrity and performance of the hardware may be maintained and even improved. However, to improve certain metrics, some hardware is required to perform at a relatively high level. For example, hardware may be required to improve TTFT or token/s. Attempting to increase performance in these areas requires a very high level of computation, and thus, the hardware running such computations will experience significant heat-generation. A water-based cooling unit may cool a hardware component somewhat, but for the purposes of improving metrics like TTFT and token/s, the water-based coolant may not be able to dissipate heat quickly enough to make a significant improvement to such metrics.

This disclosure describes a system with a dual cooling system including a coolant distribution unit (CDU) and a cryogenic cooling unit (CCU). The dual cooling system is configured to be adaptive to peak performance and to allow a quick response for quick load balancing. It allows to balance short term performance spikes and offer steady state high efficiency cooling. The system performance can be controlled in a programmed way using a wider range of cooling fluid temperatures. Combining software and hardware the adaptive and predictive software and job schedule provides the dynamic performance boost using the cryogenic cooling system to sub cool (<−100 C) to overclock frequencies and take advantage of superconducting material performance behaviors. Superconductor materials may include substances which can conduct electricity without resistance when cooled below a certain critical temperature. Unlike regular conducting materials, which have some resistance and lose energy as heat, superconductors maintain zero electrical resistance and expel magnetic fields. Furthermore, whereas traditional metallic conductors gradually decrease resistance without hitting zero resistance, super conductor materials may decrease resistance down to zero resistance once critical temperature is achieved. But if the superconducting material is cooled to a sufficiently cold temperature, the superconducting material will have a greater resistance relative to a conventional conducting metal. In some example embodiments, the superconductor materials may include one or more materials composed of compounds such as hydrogen-rich superhydrides or layered crystal structures which may maintain superconductivity without the need for extreme cryogenic cooling. As a nonlimiting example, some of the system discussed herein may include may leverage high-pressure environments for stabilizing superconducting phases at relatively high temperatures (e.g., room temperature or other temperatures above conventional cryogenic temperatures). By adding the ability to be cryogenic cooled, the performance can be increased, even for a fracture of the time, only when it is needed. The CDU may distribute a water-based coolant at non-freezing temperatures, and the CCU may distribute a cryogenic fluid (e.g. nitrogen or helium) at extremely cold temperatures, such as, without limitation, below −50 degrees Celsius. The CDU and the CCU may both be connected to one or more heat-generating hardware components by manifolds, including the same hardware components. The hardware components may include two different cooling loops: one CDU cooling loop to circulate the water-based coolant, and the CCU to circulate the cryogenic fluid. These cooling loops may cover different or overlapping portions of the hardware component, such as, e.g., at or proximate a CPU or GPU. In example embodiments, the CCU may be used for load-bearing computation. A controller may receive various information relevant to the operation of the hardware, including, without limitation, hardware temperature, hardware performance, and upcoming workloads. The controller may adjust the activation of the CCU and the flow rate of the cryogenic fluid in response to the hardware temperature information and hardware performance metrics, such as, e.g., when the hardware components are emitting heat past a predetermined threshold. Furthermore, the controller may include an adaptive software to increase or decrease the use of the CCU within certain server racks. For example, a particular server rack may require the cooling performance of the CCU, but in a different set of circumstances, a different server rack may require the CCU based on a change in performance. the adaptive software monitors different racks in the data center and identifies weak links. It can adjust the proportion of cryogenic and regular cooling to optimize performance. The software monitors the performance of different racks and adjusts the cooling system accordingly. This ensures that the weakest link in the data center is always optimized for better performance. Furthermore, the controller may include a predictive software or machine learning model that may predict when and where (in which server rack) the CCU should be activated to improve the hardware's performance regarding one or more metrics, such as TTFT and tokens/s. The predictive software, which can analyze past performance and predict future cooling needs based on changing circumstances. This allows for proactive adjustments to the cooling system. the software can be integrated with network management systems to control cooling based on network congestion and other critical factors.

In some example embodiments, the CCU and CDU system may be used to improve computational pipelines. Computational pipelines involve distributions of computational tasks among multiple nodes (computing devices) with various nodes executing one or more computational sub-tasks. Data input into a particular node may be output data generated by a previous node as part of a computational sub-task assigned to the previous node. Various nodes may include different processing and memory devices and may specialize in different types of computational sub-tasks. Some nodes may be capable of efficient serial processing while some nodes may more efficiently perform graphics processing, and so on. Data may be transferred between different nodes via networks.

Computational pipelines that distribute sub-tasks among multiple nodes enable scaled execution of computational tasks with dedicated nodes performing assigned functions. Such specialization of distributed computing systems result in an efficient utilization of hardware and software resources. Computationally-intensive applications may include image and video processing, medical imaging, simulation and rendering, object recognition, and so on. In at least one embodiment, applications may use machine learning algorithms (including use of one or more neural network models). One or more sub-tasks assigned to a given node may be executed using computational resources of a separate computing device (e.g., server) or multiple computing devices. In at least one embodiment, multiple nodes may be executed on different resources of the same computing device. Depending on a sub-task being assigned to a particular node, the sub-task may be executed on one or more CPUs (e.g., for serial or heavy computational processing), one or more GPUs (for parallel, e.g., graphics, processing), or a combination of CPU(s) and GPU(s). In some instances, CPU and/or GPU may be physical processing units (physical CPU and/or physical GPU). In some implementations, CPU and/or GPU may be virtual CPU (vCPU) and/or virtual GPU (vGPU) supported by physical processing units, with each physical CPU and/or GPU supporting operations of multiple vCPUs and/or vGPUs. In some instances, a physical processing device of a particular type (e.g., a physical CPU) may support operation of virtual processing devices of multiple types. For example, a single physical CPU (or physical GPU) may support a one or more vCPUs and one or more vGPUs. A reference throughout this disclosure to a CPU and/or GPU should be understood to apply to both physical or virtual respective processing units.

Efficiency of the pipeline execution depends on the optimal allocation of resources, e.g., on optimal distribution of sub-tasks among nodes. A number of problems and challenges may be encountered in optimization of a pipeline execution. For example, tasks that are assigned to CPU(s) may be more efficiently executed on GPU(s). Similarly, a task assigned to and executed on a CPU or GPU may not be utilizing the respective processing devices efficiently, and so on. In many such or similar instances, it may be difficult for a developer to identify these inefficiencies. In some instances, a bottleneck can be formed when too many sub-tasks are scheduled for CPU execution while GPU resources are idling (or vice versa). In some instances, application developers may use toolkits (which may include multiple sequences of pre-packaged processor operations or routines) that interact with CPU(s) and/or GPU(s) in a way that may be unknown to the developer (or at least partially obscured). As a result, the developer's efforts to optimize application execution may be limited by the architecture of the toolkits. In some instances, multiple tasks (each corresponding to a different pipeline) may be executed concurrently on the same shared distributed computing resources (e.g., processing, memory, network resources, etc.). Optimization of such a concurrent execution may be enabled by tracking how various tasks interact with each other. For example, if it is known that a first task has a peak computational demand at a first time and a second task has a peak demand at a second, different time, the CCU may be activated during the first time and the second time so that the heat generated by the computational components may be dissipated and computational speed may be likewise increased.

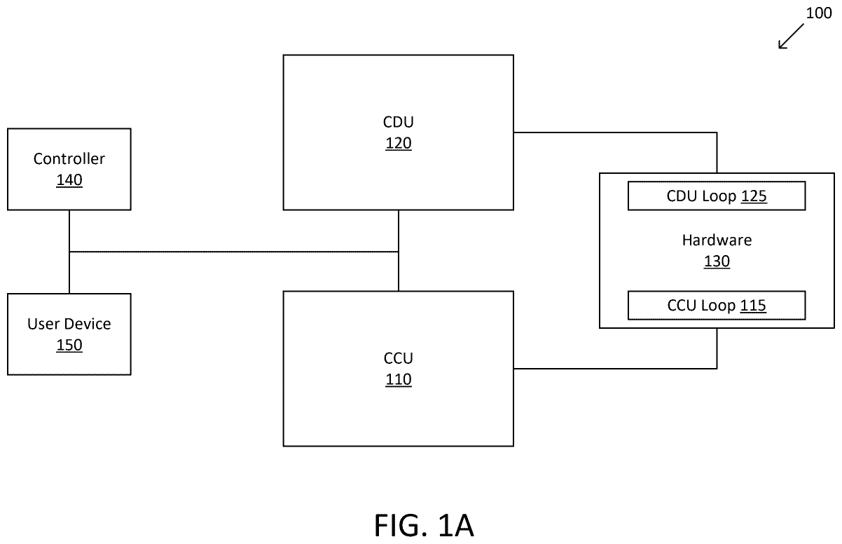

FIG. 1A illustrates a system 100 for distributing cooling fluid from a CDU 120 and a CCU 110 to one or more hardware 130. As discussed with reference to FIG. 1A, the system 100 may be used in a variety of environments that utilize the hardware 130 such as, without limitation, data centers. Certain hardware may need to be accelerated for extra performance, particularly in AI applications where the slowest part of the data center sets the completion time. The system 100 may include a CCU 110, a CDU 120, one or more hardware 130, a controller 140, and a user device 150.

The CDU 120 may distribute a cooling fluid through a manifold or tubing and into the hardware 130 via the CDU loop 125. Generally, the CDU 120 may include an apparatus designed to circulate cooling fluids, such as water or a water-glycol mixture, through a manifold or tubing to the hardware 130. By circulating the cooling fluid through the CDU loop 125, the CDU 120 may manage the temperature of heat-generating elements, such as GPUs, CPUs, servers, or other hardware. The CDU 120 may circulate the cooling fluid throughout the CDU loop 125 to absorb or dissipate heat from these heat-generating elements, thereby stabilizing temperatures and preventing overheating of the heat-generating elements. In some example embodiments, the CDU 120 may operate using a refrigeration cycle, which involves a compressor, which compresses refrigerant gas, allowing it to absorb heat from the water, thus cooling the fluid before it is circulated back to hardware 130.

The CCU 110 may distribute cryogenic fluid or cryogenic fluid through a manifold and to the hardware 130 via the CCU loop 115. Generally, the CCU 110 may include may circulate low-temperature cryogenic fluids. The CCU 110 may include a cryogenic pump, heat exchanger, and fluid reservoir. The CCU 110 may use, without limitation, a refrigeration cycle or cryocooler to maintain subzero temperatures of the cryogenic fluids.

The hardware 130 may receive both or either the cooling fluid from the CDU 120 and the cryogenic fluid from the CCU 110. The hardware 130 may be removably attached to at least a CCU loop 115 and a CDU loop 125. The CCU loop 115 may receive the cryogenic fluid from the CCU 110 and distribute the cryogenic fluid throughout one or more portions of the hardware 130. Similarly, the CDU loop 125 may receive cooling fluid from the CDU 120 and distribute the cooling fluid to one or more portions of the hardware 130. The CDU loop 125 and the CCU loop 115 may cover the same portions or different portions of the hardware 130. As a nonlimiting example, the CCU loop 115 may cover a first portion of the hardware 130, and the CDU loop 125 may cover a second portion of the hardware 130, wherein the first portion and the second portion do not overlap completely. In other example embodiments, the CCU loop 115 and the CDU loop 125 may overlap on certain areas, such as, without limitation, one or more heat-generating components such as the CPU or GPU on the hardware 130. Moreover, the CCU loop 115 and the CDU loop 125 may run on different sides of a hardware 130. In example embodiments, the hardware 130 may include a printed circuit board or a chip. The CCU loop 115 may cover some portion of a first side of the chip and then run to the second side of the chip before being discharged, whereas the CDU loop 125 may run only on either the first side or the second side of the chip. In other embodiments, the CDU loop 125 and CCU loop 115 may cover one or more portions or combinations of portions not described herein.

The hardware 130 may also include one or more sensors not illustrated herein. The sensors may collect temperature data associated with one or more components of the hardware 130. Sensors may be placed at or proximate one or more heat-generating elements such as the CPU and the GPU or any element discussed herein. Sensors may generate temperature information based off of the thermal energy associated with the heat-generating components, and transmit this sensor information to any or all of the CDU 120, the CCU 110, the controller 140, and the user device 150. Furthermore, the hardware 130 may include one or more components, such as, without limitation, a CPU, a GPU, and memory, an interface element, a power distribution unit, and any other such elements.

A controller 140 and a user device 150 may be connected to both of the CDU 120 and the CCU 110 via or more wired or wireless connections. The controller 140 may be associated without limitation with an administrator or some controller of the distribution units. The user device 150 may include any computer-enabled device that is associated with a user. The controller 140 and the user device 150 may receive information from the CDU 120 and the CCU 110, such as performance metrics, temperature information, and other information relevant to the system 100. Furthermore, the controller 140 and the user device 150 may interface with the CDU 120 or the CCU 110 to adjust a flow rate of either or both the CDU 120 and the CCU 110. Furthermore, and as described elsewhere herein, controller 140 may comprise one or more predictive software or machine learning software to predict when to activate one or both of the CDU 120 and the in this in the CCU 110, or to adjust the flow rate of the CDU 120 and the CCU 110 based on at least performance metrics, temperature information, and historical data associated with the hardware 130, the CDU 120, and the CCU 110. In other embodiments, the controller 140 may predict that the hardware 130 will experience a relatively high workload in the near future, e.g., within the next few minutes. In anticipation of this high workload and in anticipation of the relatively high amount of heat that will likely be generated from the hardware 130, the controller 140 may determine by its predictive software or machine learning model that the CCU 110 should be activated within a certain time period in order to cool the one or more heat-generating components of the hardware 130. Thus, the hardware 130 may be cooled before or at the same time that the heat-generating components are experiencing the high workload, thereby proactively dissipating a large amount of heat generation before any thermal damage may be done.

The controller 140 may send one or more commands to activate or deactivate the CCU 110. In example embodiments, the CCU 110 may be activated in circumstances in which the hardware 130 and its associated heat-generating elements are experiencing a relatively high amount of thermal energy or heat generation. Because the hardware 130 is generating a relatively high amount of heat, the controller 140 may determine that the CCU 110 should be activated, that is, the CCU should be activated to distribute cryogenic fluid into the hardware 130 to dissipate the heat from the heat-generating elements on the hardware 130. Once the heat-generating components have stopped generating a certain amount of heat based on a predetermined threshold, the controller 140 may determine that the CCU 110 is no longer necessary, and the controller 140 may transmit a command to the CCU 110 to cease distributing cryogenic fluid to the hardware 130.

Generally, the controller 140 may include one or more components of one or more devices, systems, and/or the like, referred to as modules, which carry out (i.e., perform, execute, and the like) various functions. As used in the present disclosure, a module includes both hardware and instructions. The hardware may include one or more processors, one or more microprocessors, one or more microcontrollers, one or more microchips, one or more application-specific integrated circuits (ASICs), one or more field programmable gate arrays (FPGAs), one or more graphical processing units (GPUs), one or more tensor processing units (TPUs), and/or one or more devices and/or components of any other type deemed suitable by those of skill in the art for a given implementation. In some cases, a module includes at least one functional component (e.g., an application or part of an application, a block of code, and/or the like) executing in whole or in part on one or more processors of a host system or device.

Generally, the user device 150 may include a computer-enabled device such as a computer, smart phone, tablet, control panel, or other similar device. The user device 150 may include one or more components of one or more devices, systems, and/or the like, referred to as modules, which carry out (i.e., perform, execute, and the like) various functions. As used in the present disclosure, a module includes both hardware and instructions. The hardware may include one or more processors, one or more microprocessors, one or more microcontrollers, one or more microchips, one or more application-specific integrated circuits (ASICs), one or more field programmable gate arrays (FPGAs), one or more graphical processing units (GPUs), one or more tensor processing units (TPUs), and/or one or more devices and/or components of any other type deemed suitable by those of skill in the art for a given implementation. In some cases, a module includes at least one functional component (e.g., an application or part of an application, a block of code, and/or the like) executing in whole or in part on one or more processors of a host system or device.

FIG. 1B illustrates a system 160 for cooling one or more hardware 130. The system 160 may include the controller 140, CDU 120, CCU 110, and one or more hardware 130. The CDU 120 may connect to the hardware 130 by one or more manifolds or tubings, which may circulate water-based coolant fluid to the hardware 130. The water-based coolant fluid may circulate into the hardware 130 through one or more first connecting elements, such as an inlet 172A and an outlet 172B. The inlet 172A and outlet 172B may comprise a threaded or quick disconnect (QD) fitting, which allows coolant to circulate through the hardware 130. The inlet 172A and outlet 172B may include a flow control valve, a sealing gasket, and a thermal interface. The outlet 172B may discharge coolant from the hardware 130, and the outlet 172B may incorporate a check valve. Both the inlet 172A and the outlet 172B may be designed with barbed fittings, compression fittings, or QDs. The inlet 174A and outlet 174B may allow cryogenic fluid to circulate through the hardware 130, and it may also include a flow control valve, a sealing gasket, and a thermal interface. The inlet 174A and the outlet 174B may also be designed with barbed fittings, compression fittings, or QDs.

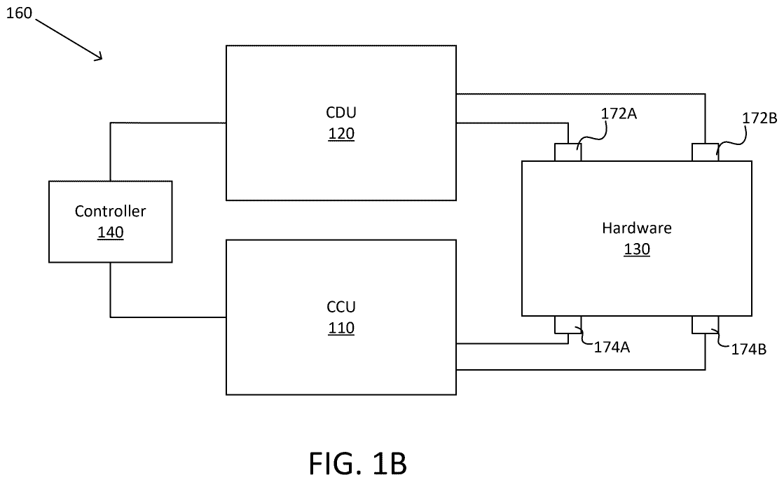

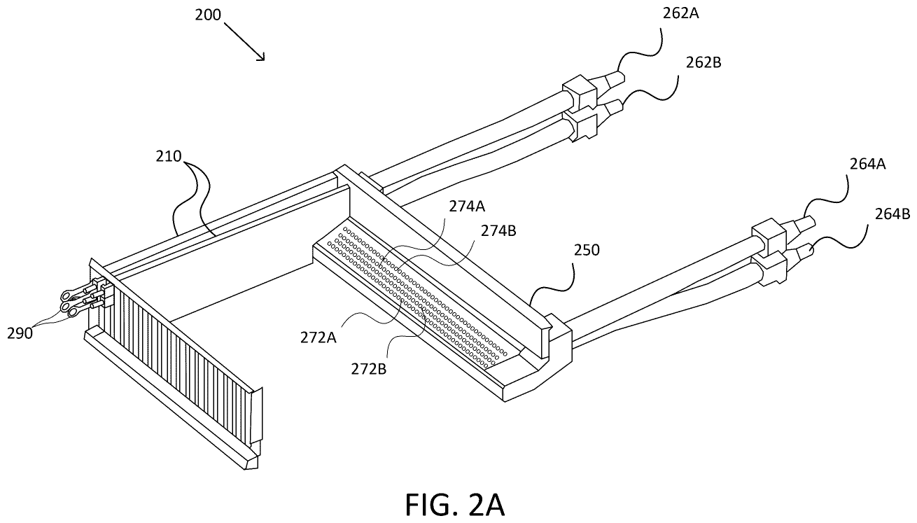

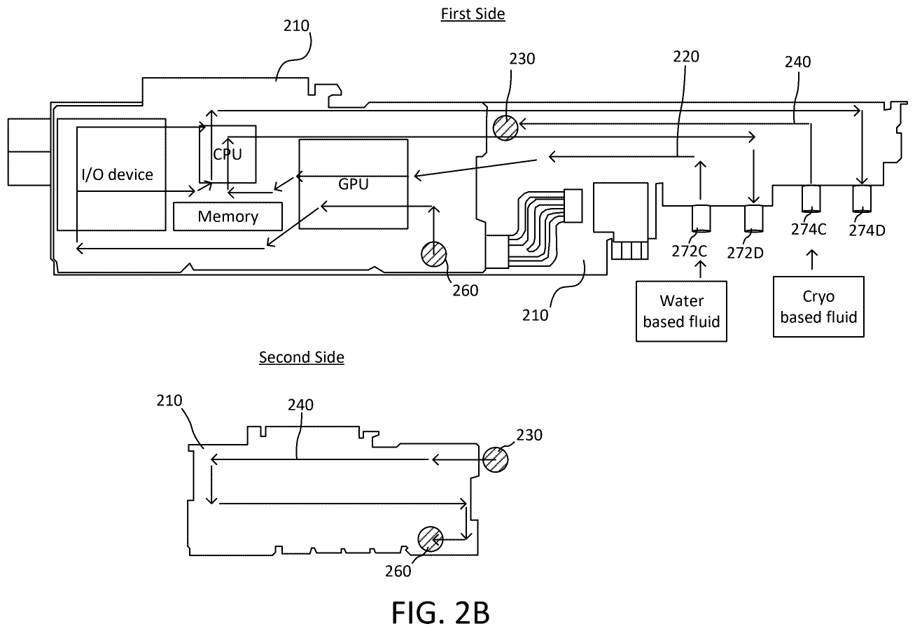

FIG. 2A illustrates an apparatus 200 for circulating water-based coolant and cryogenic fluid into one or more hardware components. Generally, the apparatus may be used in computing environments such as data centers, server rooms, server racks, and other similar environments.

The apparatus 200 may include a coolant manifold 250 into which one or more hardware 210 may be placed, slotted, fitted, or connected. As illustrated in FIG. 2A, one or more hardware 210 may fit within one or more slots on the coolant manifold 250. One or more hardware 210 may include an array of vertically oriented cards with internal fluid connections linked to dual coolant manifolds. The internal manifolds can provide blind-mate connections to cards. The cards may be pluggable AI devices which plug in manually or blind mate configurations to the coolant distribution network. The array of pluggable cards is expandable, upgradeable and serviceable. Although only a certain number of hardware 210 and corresponding slots are shown, it is understood that in other embodiments, a greater or fewer number of hardware 210 and slots may be used. Furthermore, the hardware 210 may include one or more communication links 290 for electronically or communicatively connecting the hardware 210 with other electronic or computational hardware.

The coolant manifold 250 may include a CDU inlet 262A and a CDU outlet 262B for circulating water-based coolant through the coolant manifold 250. The water-based coolant may flow into the CDU inlet 262A and flow into the hardware 210 via a water-based coolant inlet connection 272A, which may circulate water-based coolant into the hardware 210 via a water-based coolant hardware inlet 272C with further reference to FIG. 2B. The water-based coolant may then circulate through the water-based coolant hardware loop 220 discussed with further reference to FIG. 2B. A water-based coolant hardware outlet 272D may discharge the water-based coolant back to the CDU via the water-based coolant outlet connection 272B and through the CDU outlet 262B. The dual coolant paths allow for flexibility in performance versus temperature. Generally, the CCU may provide targeted cooling for specific components, while the traditional water-based coolant may be used for other components.

The coolant manifold 250 may also include a CCU inlet 264A and a CCU outlet 264B for circulating cryogenic fluid through the coolant manifold 250. The cryogenic fluid may flow into the CCU inlet 264A and flow into the hardware 210 via a cryogenic fluid inlet connection 274A, which may circulate the cryogenic fluid into the hardware 210 via a cryogenic fluid hardware inlet 274C with further reference to FIG. 2B. The cryogenic fluid may then circulate through the cryogenic fluid hardware loop 240 discussed with further reference to FIG. 2B. A cryogenic fluid hardware outlet 274D may discharge the cryogenic fluid back to the CCU via the cryogenic fluid outlet connection 274B and through the CCU outlet 264B.

The water-based coolant inlet connection 272A and water-based coolant outlet connection 272B may removably connect with the water-based coolant hardware inlet 272C and water-based coolant hardware outlet 272D respectively by one or more barbed fittings, compression fittings, QDs, threaded fittings, snap fittings, or any other suitable fitting. Similarly, the cryogenic fluid inlet connection 274A and cryogenic fluid outlet connection 274B may removably connect with the cryogenic fluid hardware inlet 274C and cryogenic fluid hardware outlet 274D, respectively, by one or more barbed fittings, compression fittings, QDs, threaded fittings, snap fittings, or any other suitable fitting.

FIG. 2B illustrates a first side and second side of an example hardware 210. The hardware 210 may include one more computing or power components including, without limitation, one or more CPUs, GPUs, memories, I/O devices, and power elements. Although only a certain number of computing and power components are illustrated on the hardware 210, it is understood that in other example embodiments, a greater or fewer number of components may be present, or different components than those illustrated and discussed herein may be present.

The hardware 210 may include a cryogenic fluid hardware inlet 274C and cryogenic fluid hardware outlet 274D to circulate cryogenic fluid through the cryogenic fluid hardware loop 240. The hardware 210 may further include a water-based coolant hardware inlet 272C and water-based coolant hardware outlet 272D to circulate water-based coolant through the water-based coolant hardware loop 220. The cryogenic fluid hardware loop 240 may cover a first portion of the hardware 210, and the water-based coolant hardware loop 220 may cover a second portion of the hardware 210. In example embodiments, the water-based coolant hardware loop 220 may circulate water-based coolant on or proximate to one or more heat-generating components such as a GPU and CPU. As illustrated in FIG. 2B, the water-based coolant hardware loop 220 transverses the first side of the hardware 210, but not the second side of the hardware 210. The cryogenic fluid hardware loop 240 may circulate cryogenic fluid at or proximate to at least some of the same heat-generating components as the water-based coolant hardware outlet 272D, such as the GPU and CPU. In some example embodiments, and as illustrated in FIG. 2B, the cryogenic fluid hardware loop 240 may also circulate cryogenic fluid at or proximate to one or more additional components such as a memory and I/O device.

The hardware 210 may include a first port 230 and a second port 260. The first port 230 and the second port 260 may be passthrough holes which allow the cryogenic fluid hardware loop 240 to pass from the first side of the hardware 210 to the second side of the hardware 210. As illustrated in FIG. 2B, the first port 230 may allow the cryogenic fluid hardware loop 240 to passthrough from the first side of the hardware 210 to the second side of the hardware 210 proximate to an edge or side of the hardware 210, e.g., a top edge of the hardware 210. On the second side of the hardware 210, the cryogenic fluid hardware loop 240 may cover one or more portions of the second side of the hardware 210. As illustrated in FIG. 2B, the cryogenic fluid hardware loop 240 may snake or zig-zag across the second side of the hardware 210, including at least a portion of the second side. In other example embodiments, the cryogenic fluid hardware loop 240 may be patterned differently and cover more or less of the second side of the hardware 210 as illustrated. The cryogenic fluid hardware loop 240 may be designed to cover portions of the second side of the hardware 210 which are proximate to the computing and power elements on the first side of the hardware 210, e.g., the portions on the second side of the hardware 210 which are opposite the computing and power elements on the first second. Upon circulating throughout the second side of the hardware 210, the cryogenic fluid hardware loop 240 may enter the second port 260 and pass back to the first side of the hardware 210. Back on the first side of the hardware 210, the cryogenic fluid hardware loop 240 may circulate at or proximate one or more computing or power elements, including, without limitation, a GPU, CPU, and I/O device. In other embodiments, the cryogenic fluid hardware loop 240 may cover a fewer or greater number of components, or different components than those illustrated or discussed herein. As illustrated, the cryogenic fluid hardware loop 240 flows near these components and even branches off between the I/O device and the CPU before reintegrating. The cryogenic fluid hardware loop 240 may be designed with other patterns not illustrated herein. After circulating through the first side of the hardware 210, the cryogenic fluid hardware loop 240 may be discharged through the cryogenic fluid hardware outlet 274D.

In example embodiments, the first port 230 and the second port 260 may be holes which are designed to fit the cryogenic fluid hardware loop 240 with any amount of allowance, including, without limitation, little to no allowance. In some example embodiments, the first port 230 and the second port 260 may be designed with an O-ring or gasket to create a seal with the cryogenic fluid hardware loop 240.

As illustrated in FIG. 2B, the cryogenic fluid hardware loop 240 and water-based coolant hardware loop 220 may cover at least some separate areas of the first side of the hardware 210, although in some embodiments both the water-based coolant hardware loop 220 and the cryogenic fluid hardware loop 240 may each circulate their respective fluids proximate to at least some of the same heat-generating components such as the CPU and GPU. In some embodiments, the CCU associated with the cryogenic fluid hardware loop 240 may be selectively activated, e.g., in response to a predicted workload, performance metric, temperature data, or any other information which may prompt a controller to determine that the cryogenic fluid hardware loop 240 is needed to boost performance of or otherwise dissipate heat from the computing and power components on the hardware 210. As a nonlimiting example, a controller may determine that the computing and power components on the hardware 210 (e.g., the GPU and CPU) are emitting a relatively high amount of heat, e.g., 130 degrees Celsius. In another nonlimiting example, a controller may determine that the performance metrics of the hardware 210 indicate that the computing components of the hardware 210 are being overclocked or strained. In another nonlimiting example, a controller may predict that although the computing and power components are not currently being strained, those computing and power components may soon be strained by an upcoming workload. In any of these nonlimiting examples, the CCU may be activated for a certain time period in order to cool the one or more heat-generating components on the hardware 210. After the controller determines that the hardware 210 has been sufficiently cooled (e.g., based on temperature data, performance metrics, or predicted decline in workload), the CCU may be deactivated, and the cryogenic fluid hardware loop 240 may stop circulating cryogenic fluid. In example embodiments and as discussed elsewhere herein, the cryogenic fluid hardware loop 240 and the water-based coolant hardware loop 220 may operate simultaneously. The water-based coolant hardware loop 220 may continue to operate before the activation cryogenic fluid hardware loop 240, during the activation cryogenic fluid hardware loop 240, and after the deactivation of the cryogenic fluid hardware loop 240.

In FIGS. 2A and 2C, the water-based coolant may be thermally insulated from the cryogenic fluid. In some example embodiments, thermal insulation may be integrated onto the surfaces of the hardware 210 or in one or more vacuum-chambered cavities between the water-based coolant hardware loop 220 and the cryogenic fluid hardware loop 240. The thermal insulation cryogenic fluid from lowering the temperature of the water-based coolant, e.g., from freezing the water-based coolant. Furthermore, the thermal insulation may prevent the cryogenic fluid from transitioning from liquid to gas. Even further, such thermal insulation prevents excessive condensation that may create ice formation on the surfaces of the hardware 210.

FIG. 2C illustrates a front view and rear view of the hardware 210 connected to the CCU loops and the CDU loops described with reference to FIG. 2A. At the front view of the hardware 210, the CCU loop and the CDU loop may be connected to the hardware 210 by one or more fluid connections such as coolant tubings or manifolds. Furthermore, the fluid connections which connect the CCU loops and CDU loops to the hardware 130 may be further connected to facility connections which connect the fluid connections to a greater facility corresponding to the hardware 210. As a nonlimiting example, the facility connections may connect the hardware 210 and fluid connections to a surrounding data center, server row, server rack, coolant or cryogenic fluid reservoir, or any other elements present in the surrounding environment of the hardware 210. Furthermore, the front of the hardware 210 may include one or more communication links 290 discussed with further reference to FIG. 2A.

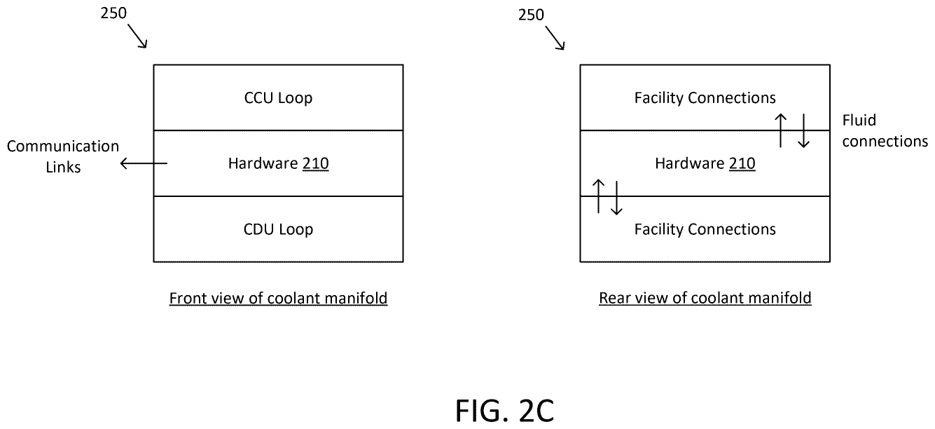

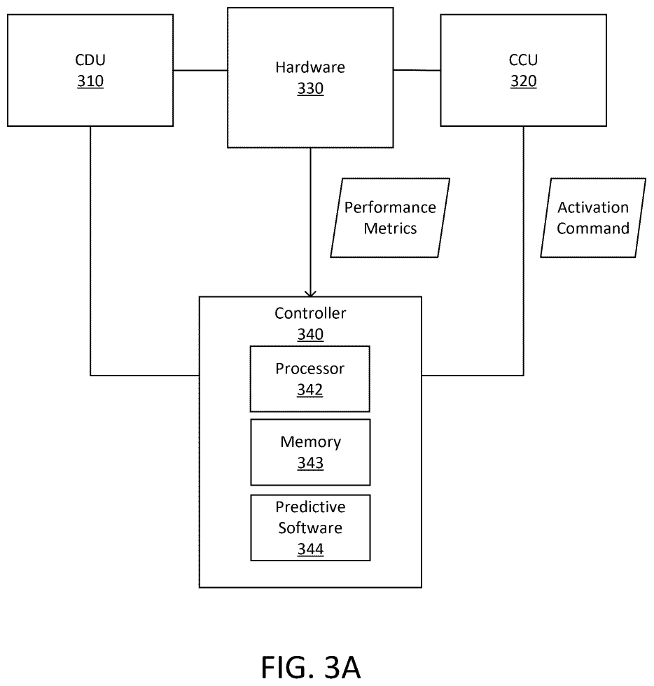

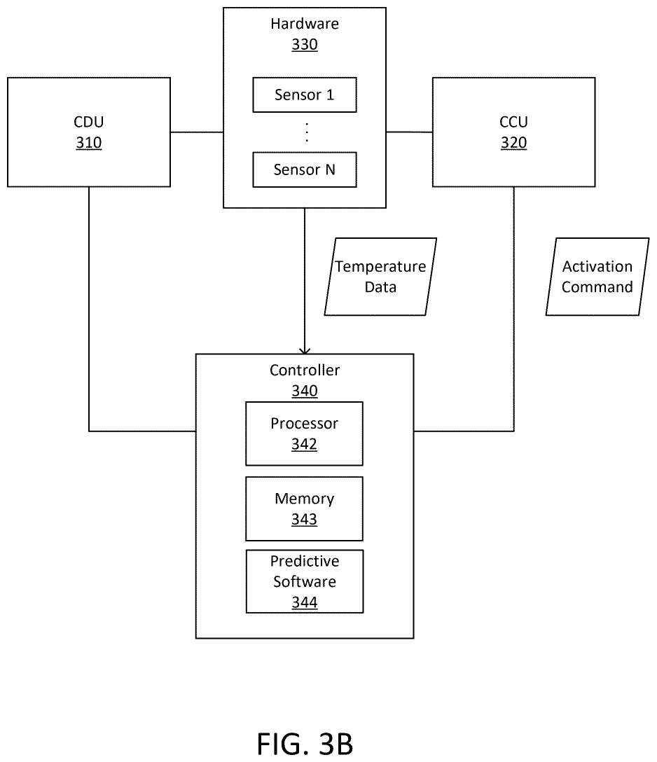

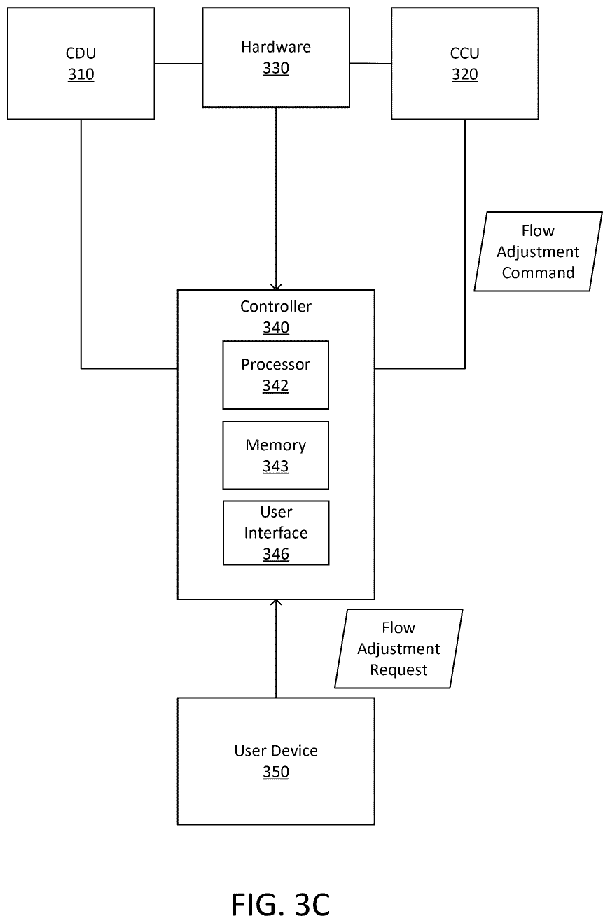

FIG. 3A illustrates a system for activating a CCU 320 based on one or more performance metrics from one or more hardware 330. The system may include a CDU 310, CCU 320, one or more hardware 330, and a controller 340. The controller 340 may include a processor 342, memory 343, and predictive software 344.

The CDU 310 may include an apparatus designed to circulate cooling fluids, such as water or a water-glycol mixture, through a manifold or tubing to the hardware 330. By circulating the cooling fluid, the CDU 310 may manage the temperature of heat-generating elements, such as GPUs, CPUs, servers, or other hardware. The CDU 310 may circulate the cooling fluid to absorb or dissipate heat from these heat-generating elements, thereby stabilizing temperatures and preventing overheating of the heat-generating elements. In some example embodiments, the CDU 310 may operate using a refrigeration cycle, which involves a compressor, which compresses refrigerant gas, allowing it to absorb heat from the water, thus cooling the fluid before it is circulated back to hardware 330. The CCU 320 may circulate low-temperature cryogenic fluids. The CCU 320 may include a cryogenic pump, heat exchanger, and fluid reservoir. The CCU 320 may use, without limitation, a refrigeration cycle or cryocooler to maintain subzero temperatures of the cryogenic fluids.

The hardware 330 may include one or more components, such as, without limitation, a CPU, a GPU, and memory, an interface element, a power distribution unit, and any other such elements. The hardware 330 and the controller 340 may be connected by a wired or wireless connection. The controller 340 may receive one or more performance metrics from the hardware 330. The performance metrics may include, without limitation, power consumption, processing load, compute utilization, indications of overclocking, or other similar metrics related to the performance of the hardware 330. The performance metrics may be specific to a given element on the hardware 330, such as CPUs, GPUs, DPUs, or other computational or power components on the hardware 330. Power consumption may be measured by one or more current or voltage sensors on the hardware 330. Processing loads and compute utilization may be measured by on-chip performance counters or embedded monitoring firmware, which may report, without limitation, CPU/GPU utilization, memory bandwidth usage, and task execution rates. In other embodiments, the performance metrics may include TTFT and output tokens throughput. The hardware 330 may transmit these performance metrics over a wired or wireless connection to the controller 340.

In example embodiments, the processor 342 may process the performance metrics and determine whether the performance metrics meet one or more predetermined thresholds for activating the CCU 320. As a nonlimiting example, a predetermined threshold for activating the CCU 320 may be 2.5 kW of power consumption or CPU/GPU utilization of 90%. These thresholds may also have time components, e.g., meeting or exceeding these thresholds for a given time, such as ten seconds. Similar thresholds may be used in other example embodiments. Once the processor 342 determines that one or more predetermined thresholds have been met, the processor 342 may generate an activation command which activates the CCU 320 to circulate cryogenic fluid to the hardware 330. The activation command may also include a time component, e.g., activate the CCU 320 for a given time period, such as one minute.

In some example embodiments, the activation command may be generated by the predictive software 344. The predictive software 344 may include one or more predictive models designed to predict whether the heat-generating components of the hardware 330 will require the cryogenic fluid from the CCU 320. In example embodiments, the controller 340 may receive performance metrics as described elsewhere herein. The predictive software 344 may access other historical and contextual information regarding the hardware 330 that allows the predictive software to predict whether the hardware 330 will require the cryogenic fluid from the CCU 320. As a nonlimiting example, the predictive software 344 may use historical performance metrics, time-based patterns, and real-time trends to anticipate when the hardware 330 will reach the predetermined workload thresholds. By analyzing historical performance metrics, the predictive software 344 may recognize recurring high-demand periods, such as an increase in compute-intensive tasks during peak hours of the day or specific days in general. In example embodiments, if the hardware 330 regularly experiences a surge in user requests for AI-drive chatbots every weekday between 12 pm and 3 pm, the predictive software 344 may anticipate a similar spike in utilization and proactively activate the CCU 320. Similarly, if a monthly data processing batch tends to overload a system on a first day of the month, the predictive software 344 may preemptively adjust cooling strategies to handle the expected workload. In other example embodiments, the predictive software 344 may also detect real-time patterns that indicate an impending workload spike. If compute utilization or power consumption has been increasing over the last 10 minutes for a rate of 5% per minute, the predictive software 344 may predict that the hardware 330 will soon exceed a predefined threshold and activate the CCU 320 proactively.

The predictive software 344 may be realized as or on a distinct processing device or as a functional component executing on the controller 340. In example embodiments, the predictive software 344 is implemented on an ASIC, FPGA, or the like. The predictive software 344 may be programmed with hardwired instructions, firmware, and/or software to carry out the functions described herein as being carried out by the predictive software 344. In some embodiments, the predictive software 344 includes one or more neural networks. The predictive software 344 may be trained using a combination of historical performance data, machine learning models, and real-time monitoring inputs to anticipate when cooling adjustments will be needed. The training process may involve collecting datasets, temperature readings, power consumption levels, compute utilization rates, and cooling system responses over time. The models may include, without limitation, regression models, neural networks, or other forecasting techniques.

The controller may include any computer enabled device or server. The processor 342 may include a CPU, GPU, data processing unit (DPU), quantum processing unit (QPU), a plurality of parallel processing units (PPUs), and application-specific integrated circuits (ASICs) memory module, or power supply. QPUs configured to perform one or more operations associated with a quantum algorithm. In some embodiments, each of the one or more QPUs may include a plurality of qubits, and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

The memory 343 may include readable instructions stored on random access memory (RAM), read-only memory (ROM), erasable programmable read-only memory (EPROM), electrically erasable programmable read-only memory (EEPROM, a.k.a. EPROM), flash memory, and/or one or more other types of memory, and/or one or more other types of non-transitory computer-readable medium.

FIG. 3B may illustrate the system in which the hardware 330 contains one or more temperature sensors, including sensor 1, sensor 2, and up to any number of sensors N. The temperature sensors may include, without limitation, thermocouples, resistance temperature detectors (RTDs), or semiconductor-based temperature sensors. The temperature sensors may generally monitor the heat levels of heat-generating components in the hardware 330. The temperature sensors may include a sensing element (e.g., a thermistor), electrical contacts, and an interface circuit to convert temperature readings into an electrical signal. The temperature data itself may include a continuous or discrete stream of voltage, current, or digital signals corresponding to temperature values. Once the temperature sensors collect the temperature data, the temperature data may be transmitted via a wired or wireless connection to the controller 340. The processor 342 may receive and process the temperature data. In example embodiments, the processor 342 may determine if the temperature data exceeds one or more predetermined temperature thresholds. If so, the processor 342 may generate an activation command and transmit the activation command to the CCU 320. Upon receiving this command, the CCU 320 may initiate cryogenic fluid circulation to the hardware 330 and corresponding heat-generating components.

FIG. 3C illustrates a system for adjusting the activation or flow of the CCU 320 based on a request from a user device 350. The user device 350 may include a computer-enabled device such as a computer, smart phone, tablet, or control panel. A user associated with the user device 350 may determine that an adjustment to the cryogenic fluid flow is desired. The adjustment may be based on a desire to lower temperatures of one or more heat-generating components in the hardware 330, increase energy efficiency, or schedule a cooling for a future time. Thus, the user device 350 may generate a flow adjustment request. The flow adjustment request may be a digital command such as, without limitation, a machine-readable or computer-readable protocol. The flow adjustment command may include such commands as “increase flow by 20%,” “stop flow immediately,” “activate flow at 3:00 am for 30 minutes,” and other similar commands. Once generated, the user device 350 transmits the flow adjustment request over a wired or wireless connection to the controller 340. The controller 340 may receive the flow adjustment request via a use interface 346. Upon receiving the flow adjustment request, the processor 342 may process the flow adjustment request and generate a flow adjustment command, which translates the flow adjustment request into, e.g., control signals that the CCU 320 may interpret to execute the flow adjustment command.

FIG. 3D illustrates how time to first token (TTFT) and inter token latency (ITL) are measured. TTFT measure the elapsed time between when a system (e.g., an LLM) receives an input and when it begins generating the first output token responsive to, e.g., a user query. TTFT may be important in applications which require real-time responsiveness, such as interactive AI systems and AI chats where minimizing TTFT improves the user experience. As illustrated in FIG. 3D, TTFT is measured as the time elapsing between when the Query is received by the inference service and the first token (i.e., Token 1) is received by the user.

ITL measures the time interval between the generations of consecutive output tokens once the first token has been produced. ITL may reflect the efficiency of a model's autoregressive decoding process, including factors such as computational overhead per token and parallelization constraints. Lower ITL may be important for applications requiring smooth and continuous output generation, such as speech synthesis, live captioning, or real-time text generation. As illustrated in FIG. 3D, ITL is measured as the time elapsing between the user receiving each token, e.g., Token 1, Token 2, Token 3, and so forth. The cryogenic systems discussed herein may improve both TTFT and ITL by circulating cryogenic fluid to computational and power-providing components responsible for processing the information necessary to generate the first token and following tokens.

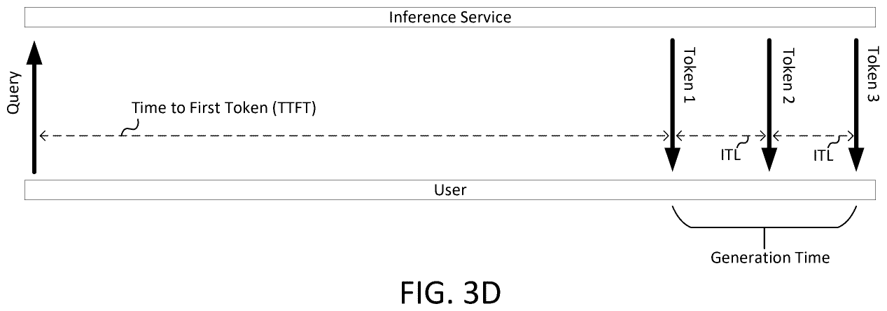

FIG. 4A and FIG. 4B illustrates a system for activating the CCU 420 in response to a temperature threshold being met with regard to one or more heat-generating components in the hardware 430. Temperature A may include a range of temperatures that may be lower than temperature B, wherein temperature A sits below an activation threshold for the CCU 420, and wherein temperature B may include a range of temperatures higher than temperature A, and is at or above the activation threshold. Temperature A and temperature B may each occur for any given periods of time. When the heat-generating components are at temperature A, the system may operate with only the CDU 410 being activated, while the CCU 420 is inactivated. Thus, the CDU 410 may be sufficient to cool the heat-generating components of the hardware 430 during a time period when the heat-generating components are experiencing temperature A. However, as workload increases or conditions change, the heat-generating components may experience temperature B for a period of time. In such example embodiments, both the CDU 410 and CCU 420 may be activated. This activation may be facilitated by the controller 440. The time period between temperature A and temperature B may vary depending on workload fluctuations, external heat conditions, or other similar factors. In some cases, the transition from temperature A to temperature B may occur rapidly, such as during a sudden spike in computational demand. In other example embodiments, the system may fluctuate between temperature A and temperature B, in which case the CCU 420 would be dynamically activated or deactivated, or the flow of cryogenic fluid from the CCU 420 would be adjusted or varied.

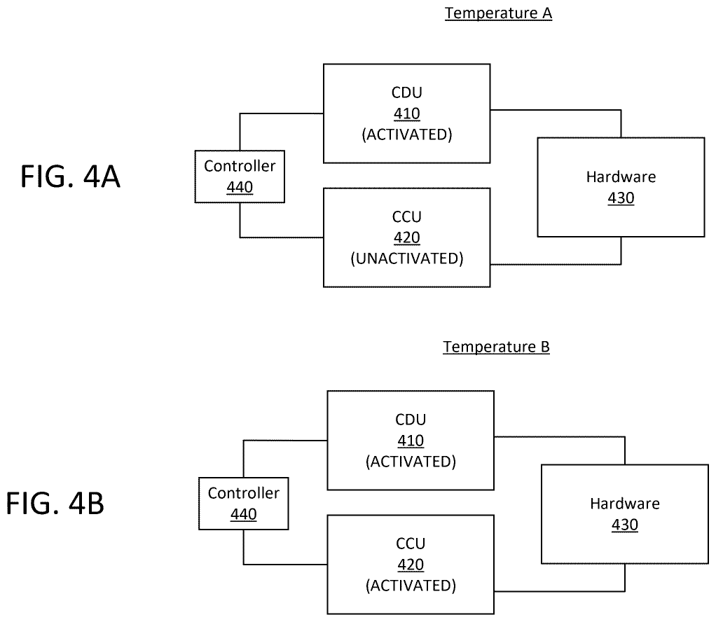

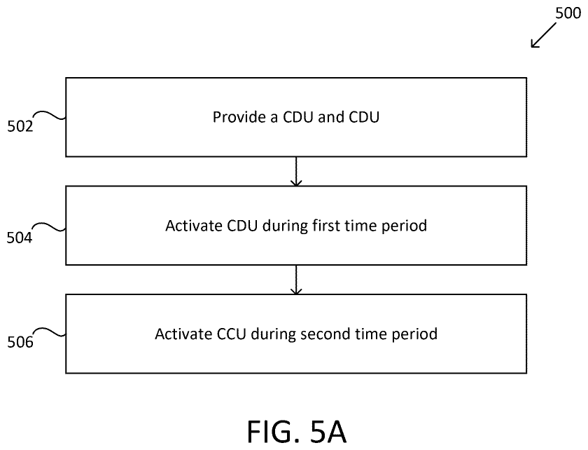

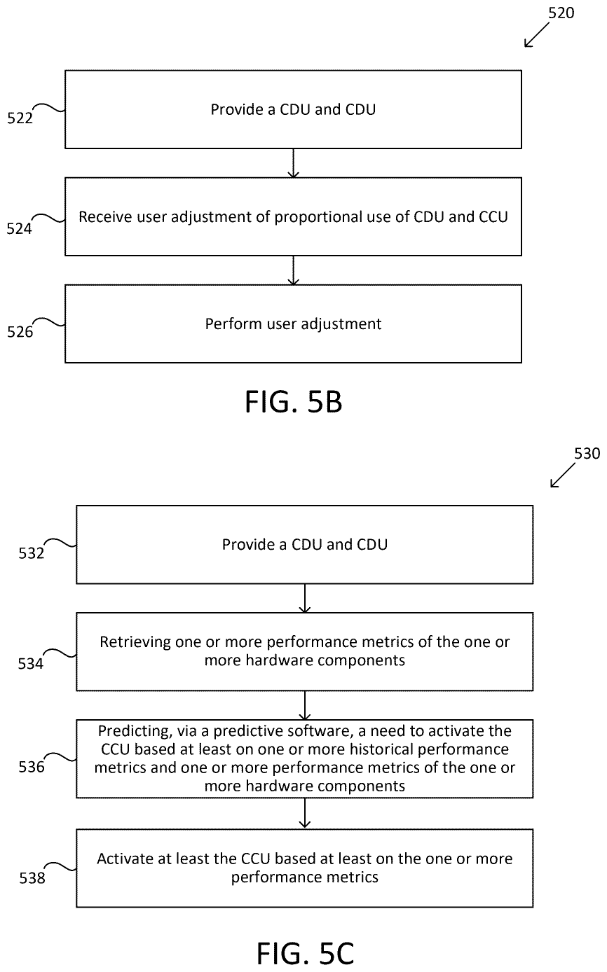

FIG. 5A illustrates a process 500. The actions performed in the process 500 may be performed in a different order than illustrated and discussed herein, and these actions may be repeated one or more times. A CDU and CCU may be provided 502 in a cooling environment such as a data center with further reference to FIGS. 1A-1B. The CDU may be activated 504 during a first time period, e.g., when a temperature of one or more heat-generating components associated with a hardware is below a certain temperature threshold. When the temperature meets or exceeds the temperature thresholds, the CCU may be activated 506 during a second time period. In example embodiments, the first time period and second time period may overlap such that the CDU and CCU are activated at the same time. In other embodiments, the first time period and second time period may not overlap completely such that either the CDU or CCU are activated independently of one another, e.g., the CDU is activated but the CCU is not, or the CCU is activated but the CDU is not and cooperatively.

In example embodiments, the cryogenic fluid may first pass along the “back” side of a printed circuit assembly (PCA) as a way of sub-cooling the electrical traces within the layers of the PCA. The cryogenic fluid can then pump on the “top” side of the card at a warmer temperature to support CMOS based devices. Concurrently the water-based coolant would provide the primary heat extraction for the high-powered silicon devices such as the GPU and CPU.

FIG. 5B illustrates a process 520. The actions performed in the process 520 may be performed in a different order than illustrated and discussed herein, and these actions may be repeated one or more times. A CDU and CCU may be provided 522 in a cooling environment such as a data center with further reference to FIGS. 1A-1B. A controller in operational communication with the CDU and CCU may receive 524 a user-generated adjustment of the proportion use of the CDU and CCU. In example embodiments, the user-generated adjustment may request a proportional use of the CDU or CCU, such as different proportions of flow rate between the CDU and CCU. As a nonlimiting example, the user may request that the CDU circulate a certain amount of fluid, e.g., 1 L/min, whereas the CCU circulates a smaller amount, e.g., 0.2 L/min. The adjustment may also be time based, e.g., to activate the CDU for 45 minutes of every hour, whereas the CCU is activated for only 15 minutes of every hour. Based on this request, the system may perform 526 the user adjustment by processing the user adjustment and communicating it to either or both the CDU and CCU.

FIG. 5C illustrates a method 530 for activating the CCU via a predictive software based on at least one or more performance metrics and historical performance metrics. As discussed herein, operational metrics may include, without limitation, power consumption, processing load, compute utilization, indications of overclocking, or other similar metrics related to the performance of the hardware. A CDU and CCU may be provided 532 in a cooling environment such as a data center with further reference to FIGS. 1A-1B. A controller may retrieve 534 one or more performance metrics of the one or more hardware components. A predictive software in the controller may process these performance metrics and, based on an additional analysis of historical performance metrics, predict 536 whether to activate the CCU. The predictive software may access other historical and contextual information regarding the hardware that allows the predictive software to predict whether the hardware will require the cryogenic fluid from the CCU. As a nonlimiting example, the predictive software may use historical performance metrics, time-based patterns, and real-time trends to anticipate when the hardware will reach the predetermined workload thresholds. By analyzing historical performance metrics, the predictive software may recognize recurring high-demand periods, such as an increase in compute-intensive tasks during peak hours of the day or specific days in general. In example embodiments, if the hardware regularly experiences a surge in user requests for AI-drive chatbots every weekday between 12 pm and 3 pm, the predictive software may anticipate a similar spike in utilization and proactively activate the CCU. Similarly, if a monthly data processing batch tends to overload a system on a first day of the month, the predictive software may preemptively adjust cooling strategies to handle the expected workload. In other example embodiments, the predictive software may also detect real-time patterns that indicate an impending workload spike. If compute utilization or power consumption has been increasing over the last 10 minutes for a rate of 5% per minute, the predictive software may predict that the hardware will soon exceed a predefined threshold and activate the CCU proactively. Based on these performance metrics and historical performance metrics, the controller may activate 538 the CCU.

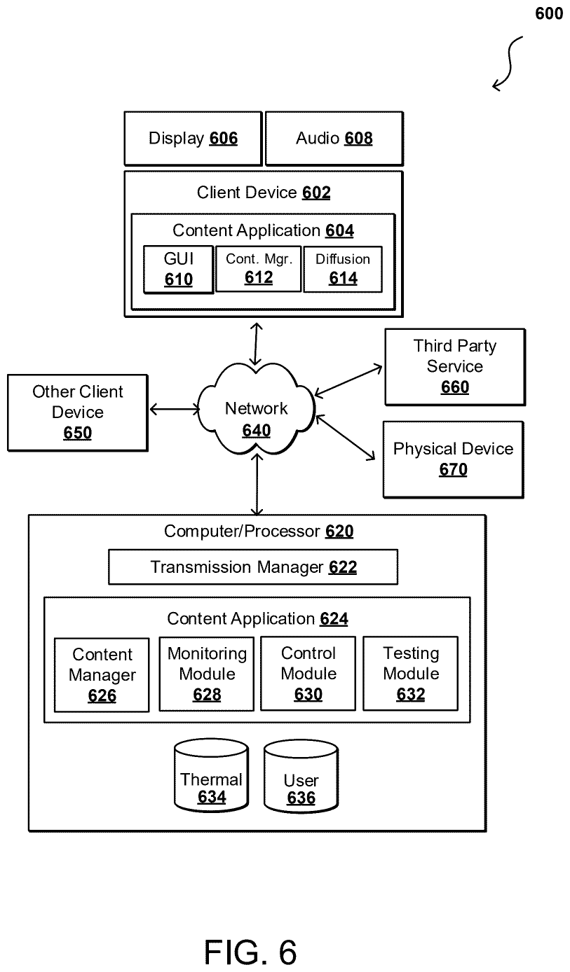

FIG. 6 illustrates an example network configuration 600 of components that may be used to implement aspects of various embodiments, such as to provide, generate, modify, encode, process, fuse, and/or transmit generated image data, calculated measurements, or other such content. In at least one embodiment, a client device 602 may generate or receive data for a session using components of a content application 604 on the client device 602 and data stored locally on that client device. In at least one embodiment, a content application 624 executing on a computer or processor 620 (e.g., a cloud server or control system) may initiate a session associated with at least one client device 602 (e.g., a vehicle or robot), as may use a session manager and user data stored in a user database 636, and may cause content such as liquid coolant or server thermal data to be selected and/or retrieved from a repository 634 to be used by a testing module 632 to calculate one or more performance metrics for a monitoring module 628, which may provide flow data or thermal data to a control module 630 to control a flow or temperature, in an environment where the data is to be used to determine appropriate operation. A content manager 626 may work with at least these various modules to perform testing and analysis, and potentially instruct any actions to be taken in response to a performance metric failing to satisfy an operational requirement. At least a portion of this data or instructional content may be transmitted to the client device 602 and/or a physical device 670 using an appropriate transmission manager 622 to send by download, streaming, or another such transmission channel. An encoder may be used to encode and/or compress at least some of this data before transmitting to the client device 602. In at least one embodiment, the client device 602 receiving such content may provide this content to a corresponding content application 604, which may also or alternatively include a graphical user interface 610, a flow monitor module 612, and a control module 614 for use in providing, synthesizing, rendering, compositing, modifying, or using content for presentation, navigation, control, (or other purposes) on or by the client device 602, such as may be transmitted to the physical device 670. In some embodiments, the computer or processor 620 and client device 602 may be able to communicate directly without needing to transmit data over a network 640, in order to avoid issues with latency and availability, etc. A decoder may also be used to decode data received over the network 640 for presentation via client device 602, such as imaging content or performance metrics through a display device 606 and audio, such as corresponding sounds or synthesized speech, through at least one audio playback device 608, such as speakers or headphones. In at least one embodiment, at least some of this content may already be stored on, rendered on, or accessible to client device 602 such that transmission over a network 640 is not required for at least that portion of content, such as where that content (e.g., thermal data) may have been previously downloaded or stored locally on a hard drive or optical disk. In at least one embodiment, a transmission mechanism such as data streaming may be used to transfer this content from the computer or processor 620, or user database 636, to the client device 602. In at least one embodiment, at least a portion of this content may be obtained, enhanced, and/or streamed from another source, such as a third party service 660 or other client device 650, that may also include a content application for generating, updating, enhancing, or providing map content. In at least one embodiment, portions of this functionality can be performed using multiple computing devices, or multiple processors within one or more computing devices, such as may include a combination of CPUs and GPUs (Graphics Processing Unit), (DPUs), (QPUs), a plurality of parallel processing units (PPUs).

In this example, these client devices can include any appropriate computing devices, as may include a desktop computer, notebook computer, set-top box, streaming device, gaming console, smartphone, tablet computer, VR headset, AR goggles, wearable computer, or a smart television. Each client device can submit a request across at least one wired or wireless network, as may include the Internet, an Ethernet, a local area network (LAN), or a cellular network, among other such options. In this example, these requests can be submitted to an address associated with a cloud provider, who may operate or control one or more electronic resources in a cloud provider environment, such as may include a data center or server farm. In at least one embodiment, the request may be received or processed by at least one edge server, which sits on a network edge and is outside at least one security layer associated with the cloud provider environment. In this way, latency can be reduced by enabling the client devices to interact with servers that are in closer proximity, while also improving security of resources in the cloud provider environment.

In at least one embodiment, such a system can be used for performing graphical rendering operations. In other embodiments, such a system can be used for other purposes, such as for providing image or video content to test or validate autonomous machine applications, or for performing deep learning operations. In at least one embodiment, such a system can be implemented using an edge device, or may incorporate one or more Virtual Machines (VMs). In at least one embodiment, such a system can be implemented at least partially in a data center or at least partially using cloud computing resources.

### Data Center

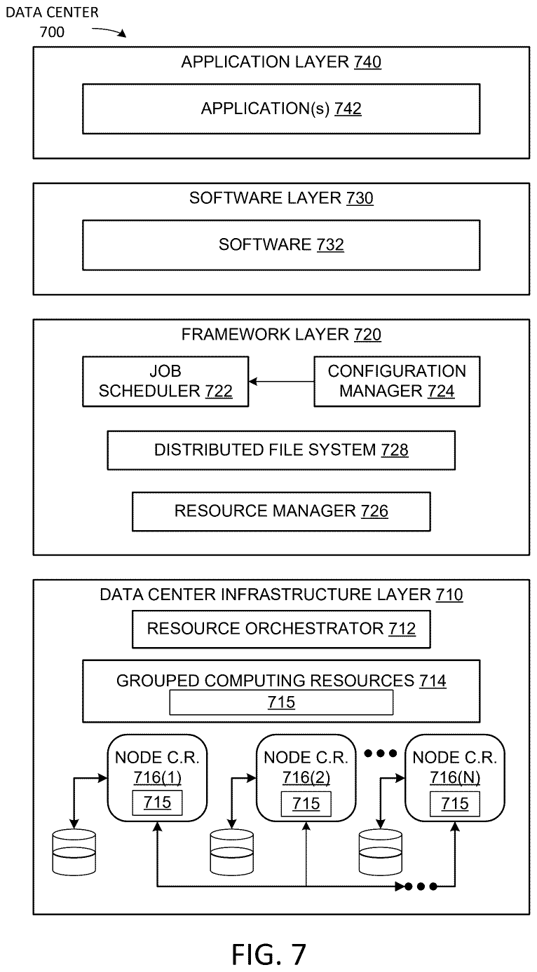

FIG. 7 illustrates an example data center 700, in which at least one embodiment may be used. In at least one embodiment, data center 700 includes a data center infrastructure layer 710, a framework layer 720, a software layer 730, and an application layer 740.

In at least one embodiment, as shown in FIG. 7, data center infrastructure layer 710 may include a resource orchestrator 712, grouped computing resources 714, and node computing resources (“node C.R.s”) 716(1)-716(N), where “N” represents any whole, positive integer. In at least one embodiment, node C.R.s 716(1)-716(N) may include, but are not limited to, any number of central processing units (“CPUs”) or other processors (including accelerators, field programmable gate arrays (FPGAs), graphics processors, etc.), memory devices (e.g., dynamic read-only memory), storage devices (e.g., solid state or disk drives), network input/output (“NW I/O”) devices, network switches, virtual machines (“VMs”), power modules, and cooling modules, etc. In at least one embodiment, one or more node C.R.s from among node C.R.s 716(1)-716(N) may be a server having one or more of above-mentioned computing resources.

In at least one embodiment, grouped computing resources 714 may include separate groupings of node C.R.s housed within one or more racks (not shown), or many racks housed in data centers at various geographical locations (also not shown). Separate groupings of node C.R.s within grouped computing resources 714 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 712 may configure or otherwise control one or more node C.R.s 716(1)-716(N) and/or grouped computing resources 714. In at least one embodiment, resource orchestrator 712 may include a software design infrastructure (“SDI”) management entity for data center 700. In at least one embodiment, resource orchestrator may include hardware, software or some combination thereof.

In at least one embodiment, as shown in FIG. 7, framework layer 720 includes a job scheduler 722, a configuration manager 724, a resource manager 726 and a distributed file system 728. In at least one embodiment, framework layer 720 may include a framework to support software 732 of software layer 730 and/or one or more application(s) 742 of application layer 740. In at least one embodiment, software 732 or application(s) 742 may respectively include web-based service software or applications, such as those provided by Amazon Web Services, Google Cloud and Microsoft Azure. In at least one embodiment, framework layer 720 may be, but is not limited to, a type of free and open-source software web application framework such as Apache Spark™ (hereinafter “Spark”) that may use distributed file system 728 for large-scale data processing (e.g., “big data”). In at least one embodiment, job scheduler 722 may include a Spark driver to facilitate scheduling of workloads supported by various layers of data center 700. In at least one embodiment, configuration manager 724 may be capable of configuring different layers such as software layer 730 and framework layer 720 including Spark and distributed file system 728 for supporting large-scale data processing. In at least one embodiment, resource manager 726 may be capable of managing clustered or grouped computing resources mapped to or allocated for support of distributed file system 728 and job scheduler 722. In at least one embodiment, clustered or grouped computing resources may include grouped computing resource 714 at data center infrastructure layer 710. In at least one embodiment, resource manager 726 may coordinate with resource orchestrator 712 to manage these mapped or allocated computing resources.

In at least one embodiment, software 732 included in software layer 730 may include software used by at least portions of node C.R.s 716(1)-716(N), grouped computing resources 714, and/or distributed file system 728 of framework layer 720. The one or more types of software may include, but are not limited to, Internet web page search software, e-mail virus scan software, database software, and streaming video content software.

In at least one embodiment, application(s) 742 included in application layer 740 may include one or more types of applications used by at least portions of node C.R.s 716(1)-716(N), grouped computing resources 714, and/or distributed file system 728 of framework layer 720. One or more types of applications may include, but are not limited to, any number of a genomics application, a cognitive compute, and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 724, resource manager 726, and resource orchestrator 712 may implement any number and type of self-modifying actions based on any amount and type of data acquired in any technically feasible fashion. In at least one embodiment, self-modifying actions may relieve a data center operator of data center 700 from making possibly bad configuration decisions and possibly avoiding underused and/or poor performing portions of a data center.

In at least one embodiment, data center 700 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 700. In at least one embodiment, trained machine learning models corresponding to one or more neural networks may be used to infer or predict information using resources described above with respect to data center 700 by using weight parameters calculated through one or more training techniques described herein.

In at least one embodiment, a data center may use CPUs, application-specific integrated circuits (ASICs), GPUs, FPGAs, DPUs, QPUs, a plurality of parallel processing units (PPUs), or other hardware to perform training and/or inferencing using above-described resources. Moreover, one or more software and/or hardware resources described above may be configured as a service to allow users to train or perform inferencing of information, such as image recognition, speech recognition, or other artificial intelligence services.

Inference and/or training logic 715 are used to perform inferencing and/or training operations associated with one or more embodiments. In at least one embodiment, inference and/or training logic 715 may be used in system FIG. 7 for inferencing or predicting operations based, at least in part, on weight parameters calculated using neural network training operations, neural network functions and/or architectures, or neural network use cases described herein.

Such components can be used in data centers that use cooling loops as described herein.

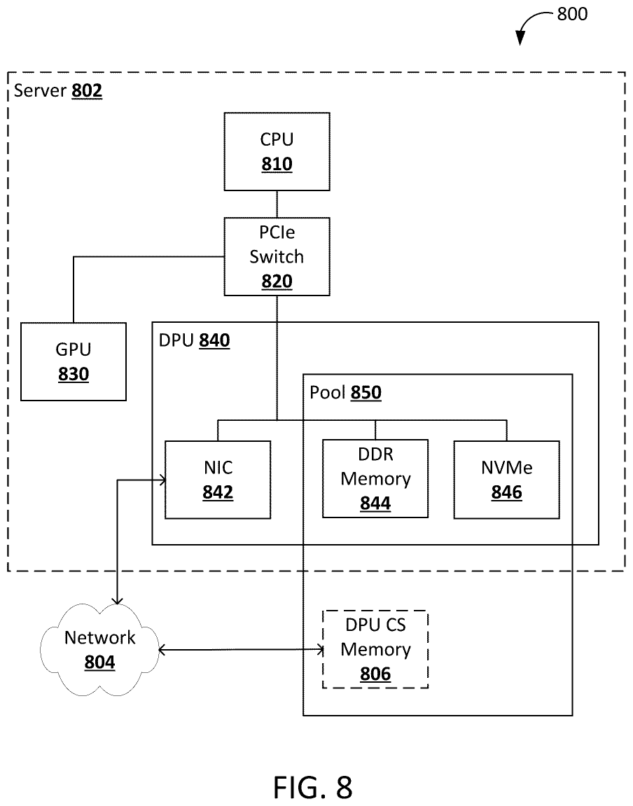

FIG. 8 illustrates an example computing environment 800 in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures. The example computing environment 800 may include a server 802 which may be used to perform HPC workloads, such as AI training or machine learning model training. In an embodiment, the server 802 may be an application instance or a compute node. The server 802 may include a CPU 810 associated with a switch 820, such as a peripheral component interconnect express (PCIe) switch, which may control at least some data transmission over communication paths interconnecting various components. In an embodiment, the CPU 810 may include a root complex processor.

The PCIe switch 820 may also be associated with a GPU 830 and a DPU 840, and may transmit data between at least some of the CPU 810, the GPU 830, the DPU 840, and other components. In an embodiment, the PCIe switch 820 may be associated with more than one GPU or more than one DPU. In another embodiment, the PCIe switch 820 may be located within the DPU 840. The PCIe switch 820 may manage the transfer of at least some data between the CPU 810, the GPU 830, and the DPU 840. In another embodiment, the number of GPUs associated with the PCIe switch 820 may be equal to the number of DPUs associated with the PCIe switch 820. In at least one embodiment, the server 802 may include, without limitation, any number of the CPUs 810, the PCIe switches 820, the GPUs 830, and/or the DPUs 840, in any combination. For example, in at least one embodiment, server 802 could include eight, sixteen, thirty-two, and/or more GPUs 830. In at least one embodiment, communication paths interconnecting various components, including but not limited to the CPU 810, the PCIe switch 820, the GPU 830, and the DPU 840, in FIG. 8 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 840 may include a network interface controller (NIC) 842, a DDR memory 844, and a non-volatile memory express (NVMe) device 846. The NIC 842 may be able to interface with a network 804, which may also interface with additional NVMe devices available to the DPU 840, such as over fabric. In an embodiment, the DPU 840 may not include the NVMe device 846. In another embodiment, the NVMe device 846 may be located on the server 802 and not on the DPU 840. In yet another embodiment, the computing environment 800 may include more than one of the NVMe device 846, such as a first NVMe device in the DPU 840 and a second first NVMe device on the server 802, and associated directly with the PCIe switch 820. In an embodiment, the DPU 840 may not include the DDR memory 844 and may include a computational storage services (CSS) in place of, or in addition to, the DDR memory 844. For example, computing environment 800 may include DPU computational storage (CS) memory 806 available to the DPU 840 as part of the CSS. The network 804 may be able to interface with the DPU CS memory 806 through the NIC 842, according to any suitable interface protocol, such as remote direct memory access (RDMA) over Ethernet, InfiniBand, Fiber Channel, etc.

The total memory of the computing environment 800 available for data storage may be expanded through the use of the DPU 840 on nodes of the system. The DPU 840 may have access to a pool 850 of memory already available to the server 802, such as double data rate (DDR) memory, on-board NVMe devices, NVMe devices over fabric, and CS. The pool 850 of memory may include at least one of the DDR memory 844, NVMe 846, and the DPU CS memory 806. The DPU 840 may also be able to access the available memory of other DPUs as part of the pool 850, and other DPUs may be able to access the available memory of DPU 840, such as the pool 850. This available memory can be accessed and utilized for data storage, without the addition of compute resources, such as compute nodes, which would be required using other solutions. The available pool 850 accessible to the DPU 840 may be provisioned for the server 802 to expand the total memory available for data storage, such as to reduce the data storage load on the CPU 810 or the GPU 830, which can instead increase the utilization of their memory for processing. For example, during training of an AI, the model states, residual states, activation functions, and checkpoints can be stored, or offloaded, on the pool 850 accessible to the DPU 840.

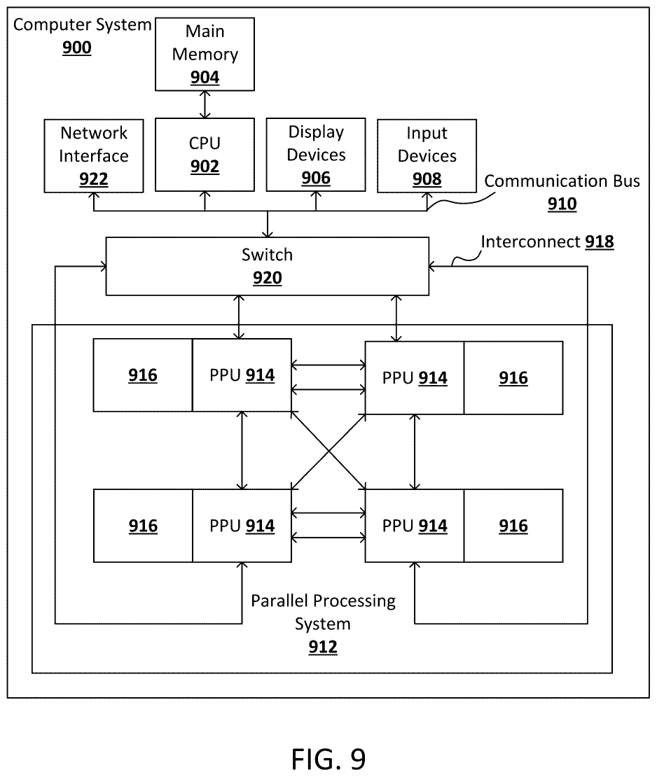

FIG. 9 illustrates a computer system 900, according to at least one embodiment. In at least one embodiment, computer system 900 is configured to implement various processes and methods described throughout this disclosure.

In at least one embodiment, computer system 900 comprises, without limitation, at least one central processing unit (“CPU”) 902 that is connected to a communication bus 910 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 900 includes, without limitation, a main memory 904 and control logic (e.g., implemented as hardware, software, or a combination thereof) and data are stored in main memory 904 which may take form of random access memory (“RAM”). In at least one embodiment, a network interface subsystem (“network interface”) 922 provides an interface to other computing devices and networks for receiving data from and transmitting data to other systems from computer system 900.

In at least one embodiment, computer system 900, in at least one embodiment, includes, without limitation, input devices 908, parallel processing system 912, and display devices 906 which can be implemented using a conventional cathode ray tube (“CRT”), liquid crystal display (“LCD”), light emitting diode (“LED”), plasma display, or other suitable display technologies. In at least one embodiment, user input is received from input devices 908 such as keyboard, mouse, touchpad, microphone, and more. In at least one embodiment, each of the foregoing modules can be situated on a single semiconductor platform to form a processing system.

In at least one embodiment, computer programs in form of machine-readable executable code or computer control logic algorithms are stored in main memory 904 and/or secondary storage. Computer programs, if executed by one or more processors, enable system 900 to perform various functions in accordance with at least one embodiment. Memory 904, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 902; parallel processing system 912; an integrated circuit capable of at least a portion of capabilities of both CPU 902; parallel processing system 912; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 900 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 912 includes, without limitation, a plurality of parallel processing units (“PPUs”) 914 and associated memories 916. In at least one embodiment, PPUs 914 are connected to a host processor or other peripheral devices via an interconnect 918 and a switch 920 or multiplexer. In at least one embodiment, parallel processing system 912 distributes computational tasks across PPUs 914 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 914, although such shared memory may incur performance penalties relative to use of local memory and registers resident to a PPU 914. In at least one embodiment, operation of PPUs 914 is synchronized through use of a command such as_syncthreads( ), wherein all threads in a block (e.g., executed across multiple PPUs 914) to reach a certain point of execution of code before proceeding.

Such components can be used in data centers that use cooling loops as described herein.

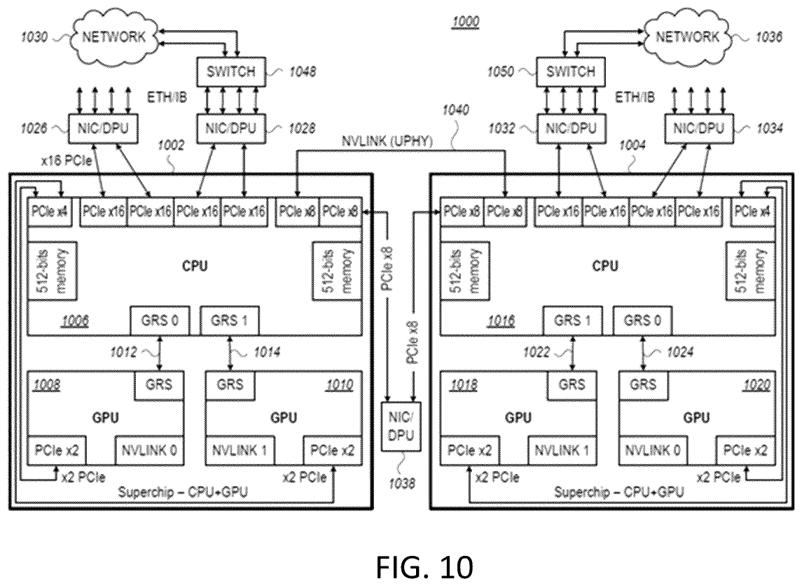

FIG. 10 is a block diagram that schematically illustrates a computing system 1000, e.g., a data center or a High-Performance Computing (HPC) cluster, in accordance with an embodiment that is described herein. System 1000 comprises a plurality of subsystems, e.g., multiple processing devices coupled to each other, multiple network devices, and multiple networks, according to at least one embodiment. Computing system 1000 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 1000 and to one or more external networks 1030, 1036. In the present example, system 1000 comprises a switch 1048 that connects NIC/DPU 1028 to network 1030, and a packet switch 1050 that connects NIC/DPU 1032 to network 1036.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1000 can include one or more CPUS and one or more GPUs.

FIG. 10 also demonstrates an example architecture of a multi-GPU architecture. As illustrated in the figure, computing system 1000 includes a processing device 1002 with a multi-GPU architecture. In particular, processing device 1002 may be a system-on-chip and includes multiple subsystems such as a CPU 1006, a GPU 1008, and a GPU 1010. CPU 1006 can be coupled to GPU 1008 via a die-to-die (D2D) or chip-to-chip (C2C) interconnect 1012, such as a Ground-Referenced Signaling interconnect (GRS interconnect). CPU 1006 can be coupled to GPU 1010 via a D2D or C2C interconnect 1014. CPU 1006 can also couple to GPU 1008 and GPU 1010 via PCIe interconnects.

CPU 1006 can be coupled to one or more NICs or DPUs, which are coupled to one or more networks. For example, as illustrated in FIG. 10, CPU 1006 is coupled to a first NIC/DPU 1026, which is coupled to a network 1030. CPU 1006 is also coupled to a second NIC/DPU 1028, which is coupled to network 1030 via switch 1048. NIC/DPU 1026 and NIC/DPU 1028 can be coupled to network 1030 over Ethernet (ETH), NVLINK or InfiniBand (IB) connections, for example.

Computing system 1000 also includes a processing device 1004 with a multi-GPU architecture. In particular, processing device 1004 includes multiple subsystems including a CPU 1016, a GPU 1018, and a GPU 1020. CPU 1016 can be coupled to GPU 1018 via a D2D or C2C interconnect 1022. CPU 1016 can be coupled to GPU 1020 via a D2D or C2C interconnect 1024. CPU 1016 can also couple to GPU 1018 and GPU 1020 via PCIe interconnects. CPU 1016 can be coupled to one or more NICs or DPUs, which are coupled to one or more networks. For example, as illustrated in FIG. 10, CPU 1016 is coupled to a first NIC/DPU 1032, which is coupled to a network 1036. CPU 1016 is also coupled to a second NIC/DPU 1034, which is coupled to network 1036 via switch 1050. NIC/DPU 1032 and NIC/DPU 1034 can be coupled to network 1036 over Ethernet (ETH), NVLINK or InfiniBand (IB) connections.

In at least one embodiment, processing device 1002 and processing device 1004 can communicate with each other via a NIC/DPU 1038, such as over PCIe interconnects. Processing device 1002 and processing device 1004 can also communicate with each other over a high-bandwidth communication interconnects 1040, such as an NVLink interconnect or other high-speed interconnects. The packet switches in FIG. 10 may comprise, for example, Nvidia Quantum-2 switches. The NICs/DPUs in the figure may comprise, for example, Nvidia Bluefield DPUs.

In various embodiments, any of the network devices of system 1000, e.g., any of NICs/DPUs 1026, 1028, 1032, 1034 and 1038, and/or any of switches 1048 and 1050, may use ILI packets in accordance with the techniques described herein. Such components can be used in data centers that use liquid cooling systems.

In example embodiments, the heat-generating element may be a silicon photonics element (e.g., SiPh die) or photonic IC. The elements may be Co-packaged forming a multichip-module (MCM) assembly.

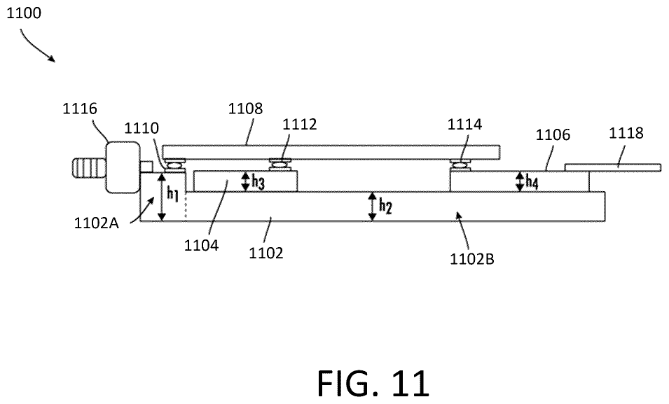

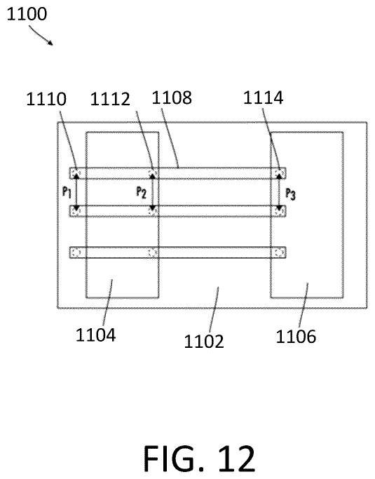

With reference to FIGS. 11 and 12, a cross-sectional view and a top plan view, respectively, of an optoelectronic component 1100 are illustrated. In some embodiments, the optoelectronic component 1100 may include a substrate 1102. The substrate 1102, for example, may be a printed circuit board, a metal carrier, an organic carrier, and/or a ceramic carrier. In some embodiments, the height of the substrate 1102 may vary. In this regard, for example, a first portion 1102A of the substrate 1102 may have a height h1 and a second portion 1102B of the substrate 1102 may have a height h2. In some embodiments, an electronic integrated circuit 1104 may be supported by the substrate 1102. The electronic integrated circuit 1104 may be any type of electronic integrated circuit. For example, the electronic integrated circuit 1104 may be a digital signal processor, a modulator driver, and/or a transimpedance amplifier. In some embodiments, there may be more than one electronic integrated circuit supported by the substrate 1102. In some embodiments, the electronic integrated circuit 1104 may have a height h3. In some embodiments, the optoelectronic component 1100 may support more than one electronic integrated circuit. In some embodiments, a photonic integrated circuit 1106 may be supported by the substrate 1102. The photonic integrated circuit 1106 may be any type of photonic integrated circuit. For example, the photonic integrated circuit 1106 may be an electro-optic modulator, a photodiode, a transmitter optical sub assembly and/or a receiver optical sub assembly. In some embodiments, the photonic integrated circuit 1106 may comprise graphene. In some embodiments, there may be more than one photonic integrated circuit supported by the substrate 1102. In some embodiments, the photonic integrated circuit 1106 may have a height h4. In some embodiments, the heights h1, h2, h3, and h4 may be different. For example, depending on the electronic integrated circuit and photonic integrated circuit used, the height h3 may be greater than the height h4, or vice versa.

In some embodiments, the optoelectronic component 1100 may include one or more optical fibers 1118 connected to the photonic integrated circuit 1106. The one or more optical fibers 1118 may be configured to connect the optoelectronic component 1100 to other optical components and/or devices. In some embodiments, a port 1116 may be connected to the substrate 1102. The port 1116 may be configured to connect the optoelectronic component 1100 to other electronic components and/or devices. In some embodiments, the optoelectronic component 1100 may be configured to operate at speeds greater than 25 Gb/s.

The optoelectronic component 1100 may include a plurality of substrate interconnect connectors 1110 disposed on the substrate 1102, a plurality of electronic integrated circuit interconnect connectors 1112 disposed on the electronic integrated circuit 1104, and a plurality of photonic integrated circuit interconnect connectors 1114 disposed on the photonic integrated circuit 1106. The plurality of substrate interconnect connectors 1110, the plurality of electronic integrated circuit interconnect connectors 1112, and the plurality of photonic integrated circuit interconnect connectors 1114 may comprise any conductive material (e.g., conductive glue and/or solder). In some embodiments, the plurality of substrate interconnect connectors 1110, the plurality of electronic integrated circuit interconnect connectors 1112, and the plurality of photonic integrated circuit interconnect connectors 1114 may be flexible. In other words, in some embodiments, the plurality of substrate interconnect connectors 1110, the plurality of electronic integrated circuit interconnect connectors 1112, and the plurality of photonic integrated circuit interconnect connectors 1114 may be manipulated such that each may be capable of taking various shapes. In some embodiments, the plurality of substrate interconnect connectors 1110 may have a pitch p1, the plurality of electronic integrated circuit interconnect connectors 1112 may have a pitch p2, and the plurality of photonic integrated circuit interconnect connectors 1114 may have a pitch p3. The pitch may refer to the distance between each of the plurality of interconnect connectors. In some embodiments, the pitch p1, pitch p2, pitch p3, may be different. For example, the pitch p2 of the plurality of electronic integrated circuit interconnect connectors 1112 may be 1.25 mm while the pitch p3 of the plurality of photonic integrated circuits may be 1.5 mm.

In some embodiments, the optoelectronic component 1100 may include a first plurality of cable connectors 1108. In some embodiments, each of the first plurality of cable connectors 1108 may be connected to and in communication with the substrate 1102, the electronic integrated circuit 1104, and the photonic integrated circuit 1106 via respective interconnect connectors. In other words, the first plurality of cable connectors 1108 may be connected to and in communication with the substrate 1102 via the plurality of substrate interconnect connectors 1110, the electronic integrated circuit 1104 via the plurality of electronic integrated circuit interconnect connectors 1112, and the photonic integrated circuit 1106 via the plurality of photonic integrated circuit interconnect connectors 1114. As such, the first plurality of cable connectors 1108 may be used to facilitate communication between the substrate 1102, the electronic integrated circuit 1104, and the photonic integrated circuit 1106.

In some embodiments, the first plurality of cable connectors 1108 may define a first layout. In some embodiments, the first layout may define the overall connectivity of the optoelectronic component 1100.

In some embodiments, the optoelectronic component 1100 may include a substrate 1102. The substrate 1102, for example, may be a printed circuit board, a metal carrier, an organic carrier, and/or a ceramic carrier.

The electronic integrated circuit 1104 may be any type of electronic integrated circuit. For example, the electronic integrated circuit 1104 may be a digital signal processor, a modulator driver, and/or a transimpedance amplifier. In some embodiments, there may be more than one electronic integrated circuit supported by the substrate 1102.

In some embodiments, a photonic integrated circuit 1106 may be supported by the substrate 1102. The photonic integrated circuit 1106 may be any type of photonic integrated circuit. For example, the photonic integrated circuit 1106 may be an electro-optic modulator, a photodiode, a transmitter optical sub assembly and/or a receiver optical sub assembly.

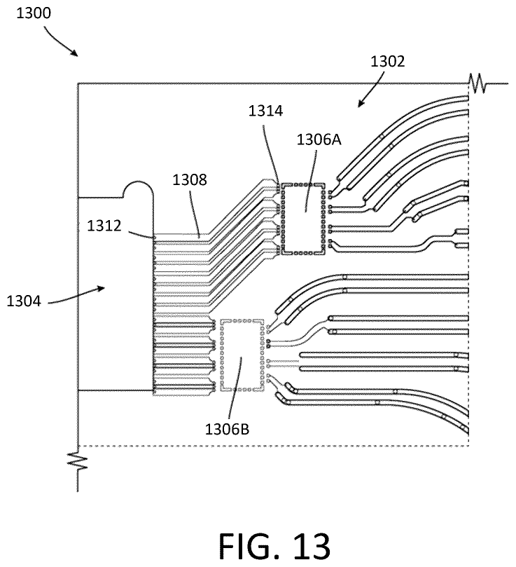

For example, with reference to FIG. 13, the connectivity defined by the first layout in the illustrated example is such that an electronic integrated circuit 1304 is connected to a first photonic integrated circuit 1306A and a second photonic integrated circuit 1306B via cable connectors 1308. In some embodiments, the first plurality of cable connectors 1308 may be interchangeable with other pluralities of cable connectors that define different layouts. The different layouts may alter the overall connectivity of the optoelectronic component 1300. For example, the first plurality of cable connectors 1308 may be interchangeable with a second plurality of cable connectors that define a second layout which modifies the overall connectivity of the optoelectronic component 1300. In this way, the optoelectronic component 1300 may be easily modified to obtain desired capabilities by interchanging cable connectors.

In some embodiments, the first plurality of cable connectors 1308 may be flexible. This may help ensure that the first plurality of cable connectors 1308 may be used with a variety of substrates, electronic integrated circuits, and photonic integrated circuits. For example, the substrate, electronic integrated circuit, and/or photonic integrated circuit may be from different manufacturers, may be a different type of integrated circuit or substrate, and/or may have different capabilities. For example, the substrate 1302, electronic integrated circuit 1304, and the photonic integrated circuit 1306A, 1306B may have different heights (e.g., height h3 of the electronic integrated circuit 1304 may be greater than height h4 of the photonic integrated circuit 1306A, 1306B). The flexibility of the first plurality of cable connectors 1308 enables the first plurality of cable connectors 1308 to bend as needed, such that components of the optoelectronic component 1300 with different heights may be accommodated and connections may be made without any modifications to the configuration of the optoelectronic component 1300 itself. Additionally, the flexibility of the first plurality of cable connectors 1308 may enable the first plurality of cable connectors 1308 to be used with a variety of substrates, electronic integrated circuits, and photonic integrated circuits that have interconnect connectors with different pitches. For example, if the pitch p2 of the plurality of electronic integrated circuit interconnect connectors 1312 is less than the pitch p3 of the plurality of photonic integrated circuit interconnect connectors 1314, the first plurality of cable connectors 1308 may bend to account for the differences in pitch and connect the electronic integrated circuit 1304 to the photonic integrated circuit 1106.

With reference to FIG. 13, a portion of an example optoelectronic component 1300 is illustrated. For example, the example optoelectronic component 1300 may be part of a 1.6 Tb/s demonstrator. The example optoelectronic component 1300 includes a substrate 1302, an electronic integrated circuit 1304 supported by the substrate 1302, a first photonic integrated circuit 1306A supported by the substrate 1302, and a second photonic integrated circuit 1306B supported by the substrate 1302. The example optoelectronic component 1300 may include a plurality of electronic integrated circuit interconnect connectors 1312 disposed on the electronic integrated circuit 1304 and a plurality of photonic integrated circuit interconnect connectors 1314 disposed on the first photonic integrated circuit 1306A and the second photonic integrated circuit 1306B. The electronic integrated circuit 1304 may be connected to and in communication with the first photonic integrated circuit 1306A and the second photonic integrated circuit 1306B via a plurality of cable connectors 1308. In the example optoelectronic component 1300, the electronic integrated circuit 1304 and the first photonic integrated circuit 1306A are situated on the substrate 1302 such that the plurality of electronic integrated circuit interconnect connectors 1312 and the plurality of photonic integrated circuit interconnect connectors 1314 disposed on the first photonic integrated circuit 1306A are not aligned with each other (e.g., one is not disposed directly opposite to the other). In such a situation, the flexibility of the plurality of cable connectors 1308 facilitating communication between the electronic integrated circuit 1304 and the first photonic integrated circuit 1306A may allow the electronic integrated circuit 1304 and the first photonic integrated circuit 1306A to be connected through manipulation of the cable connectors to accommodate the misaligned locations.

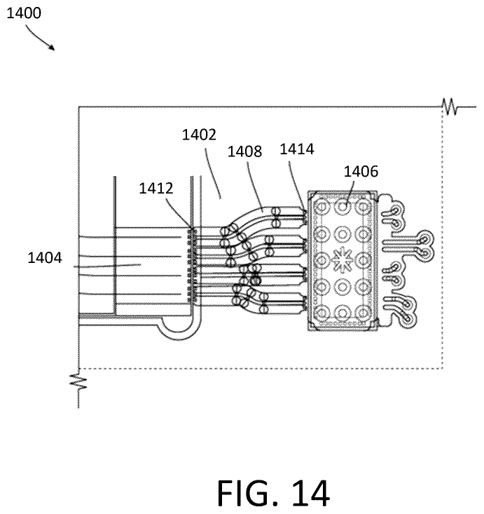

With reference to FIG. 14, another example optoelectronic component 1400 is illustrated. For example, the example optoelectronic component 1400 may be part of an octal small form factor pluggable (OSFP) transceiver. The example optoelectronic component 1400 includes a substrate 1402, an electronic integrated circuit 1404 supported by the substrate 1402, and a photonic integrated circuit 1406 supported by the substrate 1402. The example optoelectronic component 1400 may include a plurality of electronic integrated circuit interconnect connectors 1412 disposed on the electronic integrated circuit 1404 and a plurality of photonic integrated circuit interconnect connectors 1414 disposed on the photonic integrated circuit 1406. The electronic integrated circuit 1404 may be connected to and in communication with the photonic integrated circuit 1406 via a plurality of cable connectors 1408. In the example optoelectronic component 1400, the pitch of the plurality of the electronic integrated circuit interconnect connectors 1412 and the plurality of photonic integrated circuit interconnect connectors 1414 is different. In this case, the flexibility of the plurality of cable connectors 1408 facilitating communication between the electronic integrated circuit 1404 and the photonic integrated circuit 1406 may be such that the electronic integrated circuit 1404 and the photonic integrated circuit 1406 can be connected despite the differences in pitch, such as through bending or other reshaping of the cable connectors to accommodate the differences.

Silicon Photonics (SiP) is a technology that enables optical systems to be manufactured using silicon processes with silicon as the optical medium. Various optical components, such as interconnects and signal processing components, may be fabricated and integrated in a single SiP device. Some SiP devices are fabricated on a silica substrate or over a silica layer on a silicon substrate, a technology that is often referred to as Silicon on Insulator (SOI). In certain optical systems, a SiP device is attached to an external device to facilitate optical communications. However, it is generally difficult to accurately align light signals on the SiP with an external device that receives the light.

In certain optical systems, a SiP device is attached to an external device to facilitate optical communications. However, it is generally difficult to accurately align light signals on the SiP with an external device that receives the light. For instance, long range transmission of light signals is generally performed within optical fibers. When optical signals are generated or processed in a SiP device for transmission over optical fibers, the light needs to be coupled between the SiP device and the optical fibers. This coupling between the SiP device and the optical fibers is generally difficult because waveguides within the SiP device generally comprise a smaller diameter than the optical fibers. As such, a “world-to-chip” interface problem often arises in SiP technologies where coupling of light between Si wire waveguides and optical fibers, and vice versa, is generally inefficient.

Traditionally, for fiber-to-chip coupling, a fiber coupling technique using spot-size converters (SSCs) or grating couplers is employed. However, grating couplers for fiber-to-chip coupling typically provide a narrow bandwidth and/or an undesirable polarization sensitivity for certain optical applications. Furthermore, SSCs and grating couplers for fiber-to-chip coupling are generally attached to the chip through an adhesive bonding technique that results in a silicon communication chip with bundles of fibers attached thereto, resulting in increased complexity for handling and/or assembly of the chips onto other optical systems. Additionally, wafers for traditional SiP devices are generally diced (e.g., fully cut through) to create an edge for the wafer to expose waveguide facets and/or to facilitate butt attachment of the SiP device to an external device. Co-packaging may refer to the close integration of different electrical and/or optoelectronic chips in the same package.

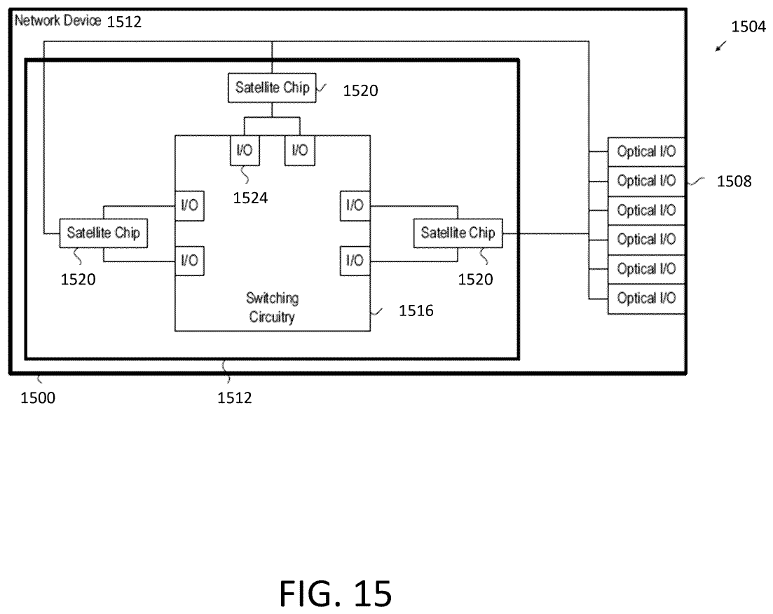

FIG. 15 is a block diagram that schematically illustrates a co-packaged Networking Device 1500, in accordance with an embodiment that is disclosed herein. The different chips that constitute a co-packaged Networking Device are assembled on a single substrate in what is typically called the MCM assembly 1512. The MCM assembly 1512 can include a switching circuitry 1516 surrounded by peripheral or satellite chips 1520. In some embodiments, the switching circuitry 1516 and surrounding satellite chips 1520 are all mounted on a common substrate, although such a configuration is not required. The MCM assembly 1512 may be provided in a larger housing of the co-packaged Networking Device 1500, positioned behind the front panel 1504. The switching circuitry 1516 may include one or more core digital Application Specific Integrated Circuits (ASICs), CPUs, GPUs, microprocessors, FPGAs, combinations thereof, and the like. The switching circuitry 1516 may include a number of input ports and/or output ports 1524. The Input/Output (I/O) ports 1524 may include electrical ports and/or optical ports. Additionally, the switching circuitry 1516 may include a combination of electrical blocks and optical blocks. The electrical blocks of the switching circuitry 1516 may include a number of electrical switches that are configured to route signals in an electrical domain. The optical blocks of the switching circuitry 1516 may include a number of optical components that are configured to generate, detect and route signals in an optical domain. The MCM assembly 1512, in some embodiments, may concern or include multiple satellite chips 1520 that are assembled on the same substrate as the switching circuitry 1516. In some embodiments, a configuration of the optical block(s) and a configuration of the electrical block(s) depends (e.g., is based on) on the number of optical ports in the I/O ports 1524.

As discussed above, optical I/Os 1508, which may also be referred to as optical connectors, are placed at the front panel 1504. As mentioned above, connectivity between the MCM assembly 1512 and optical I/Os 1508 may be transferred to the front panel 1504 through optical fibers. This connection may be made directly with an optical I/O port 1524 of the switching circuitry or may be made with one or more of the satellite chips 1520. The connection is often made with one or more of the satellite chips 1520 because the satellite chips 1520 may include the electro-optic converters and, possibly, the SERDES to natively support the connection. The satellite chips 1520 may include one or more of a DSP processor, driver, trans-impedance amplifier, laser, modulator, photodiode, serializer-deserializer, or the like.

Some embodiments of the present disclosure are directed to a multi-chip module (MCM) with a centrally positioned main die and a plurality of peripherally positioned MCM sockets configured to mechanically receive and electrically connect mezzanine packages, which may include co-packaged optics (CPO) packages and co-packaged copper (CPC) packages. Each mezzanine package may include a package substrate including a connector portion that is configured to engage the MCM socket and a main portion extending beyond the periphery of the MCM substrate. The main portion of the mezzanine package may be configured to receive optical devices and/or integrated circuits, such as via mezzanine sockets, to allow connections to be made between the optical devices and/or integrated circuits/RF copper cable connectors and the main die of the MCM. Due to the extension of the mezzanine package beyond the periphery of the MCM substrate, the physical size of the MCM substrate may remain small to reduce cost and avoid the previously discussed production challenges, while allowing connections to a number of optical devices and integrated circuits via the mezzanine packages, which occupy the relatively inexpensive space around the periphery of the MCM substrate. As used herein, the terms “co-packaged optic” (or “CPO”) and “co-packaged copper” (or “CPC”) may refer to an advanced heterogeneous integration of either optics and silicon or copper and silicon, in which either integration may be implemented on a single packaged substrate. The CPO may utilize pluggable optical modules that include an optical engine (OE) to convert optical signals to electrical signals and electrical signals to optical signals. The CPO may further be comprised of an optical component on a photonics die and an electrical component on an electrical die.

As used herein, a ball grid array (BGA) may be a type of surface-mount packaging used for integrated circuits. BGA packages use an array of metallic conductor balls arranged in a grid to permanently mount devices such as microprocessors on a PCB. The metallic conductor balls may then undergo the reflow process described above, wherein the metallic conductor balls may be preheated, then melted to bond the IC to a substrate to form an IC package.

As used herein, the term “flip chip (FC)” may refer to a method for interconnecting dies, such as semiconductor devices, IC chips, integrated passive devices, and microelectromechanical systems (MEMS), to external circuitry with solder bumps that have been deposited onto chip pads. The solder bumps may be deposited onto chip pads on the top side of the wafer during final wafer processing. The chip may be mounted to external circuitry (such as a circuit board or another chip or wafer) by “flipping” the chip, such that the chip's top side faces down and is positioned to allow the pads of the chip to align with matching pads on the external circuit. Solder is reflowed to complete the interconnect.

In the packaging of integrated circuit (IC) chips, various packaging schemes are employed, including traditional two-dimensional (2D) integrated circuit (IC) packages as well as the more recently introduced 2.5D IC and 3D IC packages. In 2D IC packages, multiple chips are mounted on a printed circuit board, where high-performance logic, lower-performance logic, memory, and analog/RF functions, and other functional elements are presented as discrete devices in separate chip packages. By contrast, in 2.5D ICs and 3D IC packages, multiple IC chips are mounted on a silicon interposer instead of a conventional package substrate. The silicon interposer, which is typically a silicon wafer, allows very small and high-density conductive traces to be formed between the multiple IC chips because the fabrication processes used to form the conductive traces are the same processes used to form the metal interconnects in the metallization layers of a silicon chip.

Compared to 2.5D IC packages and 3D IC packages, a circuit board with individually packaged chips, such as a 2D IC package, has numerous disadvantages. For example, a 2D IC package is generally larger, heavier, consumes more power, and, because the signals propagate relatively slowly across the circuit board from one chip to another, is slower than an equivalent 2.5D or 3D IC package. Furthermore, a 2D IC package has more possible points of failure, given that the soldered joints on the circuit board are more likely to fail than the electrical connections formed within an interposer. That said, troubleshooting a 2D IC package after the different chips have been mounted on the circuit board is relatively straightforward. In particular, the conductive traces carrying I/O signals between the various chips on the circuit board are easily accessible and therefore can be employed to measure specific I/O signals during troubleshooting.

By contrast, troubleshooting a 2.5D or 3D IC package is far more problematic because the I/O signals transmitted between the different chips typically are embedded in the silicon interposer and are not physically accessible. Furthermore, because 2.5D and 3D IC packages are high-bandwidth and are quite dense, typically implementations can include thousands of conductive traces routed between the different chips. One example of such an implementation is a memory bus residing in between a processor and a high-bandwidth memory chip. In such implementations, even if the traces could be physically accessed through the silicon interposer with a probe, the accurate and reliable selection of a specific conductive trace or combination of conductive traces for the purpose of troubleshooting the IC package would be very difficult, if not impossible.

In at least one embodiment, one or more parallel processor(s) incorporate circuitry optimized for graphics and video processing, including, for example, video output circuitry, and constitutes a graphics processing unit (“GPU”). In at least one embodiment, one or more parallel processor(s) incorporate circuitry optimized for general purpose processing. In at least one embodiment, components of computing system may be integrated with one or more other system elements on a single integrated circuit. For example, in at least one embodiment, one or more parallel processor(s), memory hub, processor(s), and I/O hub can be integrated into a SoC integrated circuit. In at least one embodiment, components of computing system can be integrated into a single package to form a system in package (“SIP”) configuration. In at least one embodiment, at least a portion of components of computing system can be integrated into a multi-chip module (“MCM”), which can be interconnected with other multi-chip modules into a modular computing system. In at least one embodiment, I/O subsystem and display devices are omitted from computing system.

When the light-transmitting medium is silicon, a suitable insulator includes, but is not limited to, silica and a suitable substrate includes a silicon substrate. A silicon-on-insulator wafer is a suitable platform for an optical device having a silicon light-transmitting medium positioned over a base having a silica insulator and a silicon substrate.

The device includes one or more waveguides that carry light signals to and/or from optical components. Examples of optical components that can be included on the device include, but are not limited to, one or more components selected from a group consisting of facets through which light signals can enter and/or exit a waveguide, entry/exit ports through which light signals can enter and/or exit a waveguide from above or below the device, multiplexers for combining multiple light signals onto a single waveguide, demultiplexers for separating multiple light signals such that different light signals are received on different waveguides, optical couplers, optical switches, lasers that act as a source of a light signal, amplifiers for amplifying the intensity of a light signal, attenuators for attenuating the intensity of a light signal, modulators for modulating a signal onto a light signal, modulators that convert a light signal to an electrical signal, and vias that provide an optical pathway for a light signal traveling through the device from the bottom side of the device to the top side of the device. Additionally, the device can optionally, include electrical components. For instance, the device can include electrical connections for applying a potential or current to a waveguide and/or for controlling other components on the optical device.

Various embodiments can be described by the following clauses:
1. A cooling system in a data center, comprising:
   a coolant distribution unit (CDU) operably connected to a hardware component via a first connecting element, the CDU to transfer heat from the hardware component via fluid-based coolant;
   a cryogenic cooling unit (CCU) operably connected to the hardware component via a second connecting element, the CCU to transfer heat from the hardware component via cryogenic fluid; and
   a control system to activate the CDU and the CCU either simultaneously or independently of each other.
2. The cooling system of clause 1, wherein the CDU provides water-based coolant through a first cooling loop and the CCU provides cryogenic fluid through a second cooling loop, the first cooling loop covering a first area of the hardware component and the second cooling loop covering a second area of the hardware component.
3. The cooling system of clause 2, wherein the second cooling loop traverses a first side of the hardware component and exits on a second side of the hardware component.
4. The cooling system of clause 1, wherein the control system activates the CCU based on at least one of a temperature threshold, a processing load, or a heat generation level of the hardware component.
5. The cooling system of clause 1, wherein the control system comprises an adaptive software module to:
   retrieve one or more performance metrics of the hardware component; and
   determine an activation of the CCU based at least one of the performance metrics.
6. The cooling system of clause 5, wherein the performance metrics include at least one of time to first token or output tokens throughput.
7. The cooling system of clause 1, wherein the control system comprises a predictive software module that predicts when to activate the CCU based at least on one or more historical performance data and one or more performance metrics of the hardware component.
8. The cooling system of clause 1, wherein the hardware component comprises CPUs or GPUs of one or more server racks.
9. The cooling system of cl clause aim 1, wherein the control system comprises one or more sensors to monitor a temperature of the hardware component.
10. A method comprising:
   providing a coolant distribution unit (CDU) operably connected to one or more hardware components via a first connecting element and a cryogenic cooling unit (CCU) operably connected to the one or more hardware components via a second connecting element; and
   activating, via a control system, the CDU during a first time period; and
   activating, via the control system, the CCU during a second time period.
11. The method of clause 10, further comprising allowing, via a user interface, a user to manually adjust a proportional operation of the CDU and CCU.
12. The method of clause 10, further comprising:
   retrieving one or more performance metrics of the one or more hardware components; and
   determining the activation of at least the CCU based at least on the one or more performance metrics.
13. The method of clause 10, further comprising:
   predicting, via a predictive software module, a need to activate the CCU based at least on one or more historical performance data and one or more operational metrics of the one or more hardware components.
14. The method of clause 10, wherein the first time period and second time period overlap at least in part.
15. The method of clause 10, further comprising providing multiple CDUs and CCUs to one or more additional hardware components.
16. The method of clause 10, further comprising recording an operational history of the CDU, CCU, and the one or more hardware components.
17. A processor comprising one or more logical units to adaptively control an amount of coolant supplied concurrently by each of a coolant distribution unit (CDU) and a cryogenic cooling unit (CCU) to a hardware component, the CDU being operably connected to the hardware component via a first connecting element and the CCU being operably connected to the hardware component via a second connecting element.
18. The processor of clause 17, wherein the one or more logical units comprise a predictive software module to:
   retrieve one or more performance metrics of the hardware component; and
   determine an activation of the CCU based at least on the performance metrics.
19. The processor of clause 17, wherein the one or more logical units comprise a predictive software module that predicts a need for cryogenic fluid application to the hardware component based at least on one or more historical performance data and one or more performance metrics.
20. The processor of clause 17, further to operate the CDU and CCU based at least on one or more performance metrics including time to first token and output tokens throughput.
21. A data center comprising:
   a coolant distribution unit (CDU) operably connected to a hardware component, the CDU to transfer heat from the hardware component via water-based coolant;
   a cryogenic cooling unit (CCU) operably connected to the hardware component, the CCU to transfer heat from the hardware component via cryogenic fluid; and
   a control system to activate the CDU and the CCU either simultaneously or independently of each other.
22. The data center of clause 21, further comprising thermal insulation between a CDU cooling loop and a CCU cooling loop proximate the hardware component.
23. The data center of clause 21, wherein the hardware component comprises one or more superconducting materials.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. In at least one embodiment, use of term “set” (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, term “plurality” indicates a state of being plural (e.g., “a plurality of items” indicates multiple items). In at least one embodiment, number of items in a plurality is at least two, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. In at least one embodiment, set of non-transitory computer-readable storage media comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

In at least one embodiment, an arithmetic logic unit is a set of combinational logic circuitry that takes one or more inputs to produce a result. In at least one embodiment, an arithmetic logic unit is used by a processor to implement mathematical operation such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

In the scope of this application, the term arithmetic logic unit, or ALU, is used to refer to any computational logic circuit that processes operands to produce a result. For example, in the present document, the term ALU can refer to a floating point unit, a DSP, a tensor core, a shader core, a coprocessor, or a CPU.

Accordingly, in at least one embodiment, computer systems are configured to implement one or more services that singly or collectively perform operations of processes described herein and such computer systems are configured with applicable hardware and/or software that enable performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

The techniques disclosed herein may be incorporated in any processor that may be used for processing a neural network such as, for example, a central processing unit (CPU), a graphics processing unit (GPU), an intelligence processing unit (IPU), neural processing unit (NPU), tensor processing unit (TPU), neural network processor (NNP), a data processing unit (DPU), a vision processing unit (VPU), an application specific integrated circuit (ASIC), a field-programmable gate array (FPGA), and the like. Such a processor may be incorporated in a personal computer (e.g., a laptop), at a data center, in an Internet of Things (IoT) device, a handheld device (e.g., smartphone), a vehicle, a robot, or any other device that performs inference, training or any other processing of a neural network. Such a processor may be employed in a virtualized system such that an operating system executing in a virtual machine on the system can utilize the processor.

As an example, a processor incorporating the techniques disclosed herein can be employed to process one or more neural networks in a machine to identify, classify, manipulate, handle, operate, modify, or navigate around physical objects in the real world. For example, such a processor may be employed in an autonomous vehicle (e.g., an automobile, motorcycle, helicopter, drone, plane, boat, submarine, delivery robot, etc.) to move the vehicle through the real world. Additionally, such a processor may be employed in a robot at a factory to select components and assemble components into an assembly.

As an example, a processor incorporating the techniques disclosed herein can be employed to process one or more neural networks to identify one or more features in an image or to alter, generate, or compress an image. For example, such a processor may be employed to enhance an image that is rendered using raster, ray-tracing (e.g., using NVIDIA RTX), and/or other rendering techniques. In another example, such a processor may be employed to reduce the amount of image data that is transmitted over a network (e.g., the Internet, a mobile telecommunications network, a WIFI network, as well as any other wired or wireless networking system) from a rendering device to a display device. Such transmissions may be utilized to stream image data from a server or a data center in the cloud to a user device (e.g., a personal computer, video game console, smartphone, other mobile device, etc.) to enhance services that stream images such as NVIDIA GeForce Now (GFN), Google Stadia, and the like.

As an example, a processor incorporating the techniques disclosed herein can be employed to process one or more neural networks for any other types of applications that can take advantage of a neural network. For example, such applications may involve translating from one spoken language to another, identifying and negating sounds in audio, detecting anomalies or defects during production of goods and services, surveillance of living and/or non-living things, medical diagnosis, decision making, and the like.

As an example, a processor incorporating the techniques disclosed herein can be employed to implement neural networks such as large language models (LLMs) to generate content (e.g., images, video, text, essays, audio, and the like), respond to user queries, solve problems in mathematical and other domains, and the like.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. In at least one embodiment, process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. In at least one embodiment, references may also be made to providing, outputting, transmitting, sending, or presenting analog or digital data. In various examples, processes of providing, outputting, transmitting, sending, or presenting analog or digital data can be accomplished by transferring data as an input or output parameter of a function call, a parameter of an application programming interface or interprocess communication mechanism.

Although descriptions herein set forth example implementations of described techniques, other architectures may be used to implement described functionality, and are intended to be within scope of this disclosure. Furthermore, although specific distributions of responsibilities may be defined above for purposes of description, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A cooling system in a data center, comprising:
a coolant distribution unit (CDU) operably connected to a hardware component via a first connecting element, the CDU to transfer heat from the hardware component via fluid-based coolant;
a cryogenic cooling unit (CCU) operably connected to the hardware component via a second connecting element, the CCU to transfer heat from the hardware component via cryogenic fluid; and
a control system to activate the CDU and the CCU either simultaneously or independently of each other.

2. The cooling system of claim 1, wherein the CDU provides water-based coolant through a first cooling loop and the CCU provides cryogenic fluid through a second cooling loop, the first cooling loop covering a first area of the hardware component and the second cooling loop covering a second area of the hardware component.

3. The cooling system of claim 2, wherein the second cooling loop traverses a first side of the hardware component and exits on a second side of the hardware component.

4. The cooling system of claim 1, wherein the control system activates the CCU based on at least one of a temperature threshold, a processing load, or a heat generation level of the hardware component.

5. The cooling system of claim 1, wherein the control system comprises an adaptive software module to:
retrieve one or more performance metrics of the hardware component; and
determine an activation of the CCU based at least one of the performance metrics.

6. The cooling system of claim 5, wherein the performance metrics include at least one of time to first token or output tokens throughput.

7. The cooling system of claim 1, wherein the control system comprises a predictive software module that predicts when to activate the CCU based at least on one or more historical performance data and one or more performance metrics of the hardware component.

8. The cooling system of claim 1, wherein the hardware component comprises CPUs or GPUs of one or more server racks.

9. The cooling system of claim 1, wherein the control system comprises one or more sensors to monitor a temperature of the hardware component.

10. A method comprising:
providing a coolant distribution unit (CDU) operably connected to one or more hardware components via a first connecting element and a cryogenic cooling unit (CCU) operably connected to the one or more hardware components via a second connecting element; and
activating, via a control system, the CDU during a first time period; and
activating, via the control system, the CCU during a second time period.

11. The method of claim 10, further comprising allowing, via a user interface, a user to manually adjust a proportional operation of the CDU and CCU.

12. The method of claim 10, further comprising:
retrieving one or more performance metrics of the one or more hardware components; and
determining the activation of at least the CCU based at least on the one or more performance metrics.

13. The method of claim 10, further comprising:
predicting, via a predictive software module, a need to activate the CCU based at least on one or more historical performance data and one or more operational metrics of the one or more hardware components.

14. The method of claim 10, wherein the first time period and second time period overlap at least in part.

15. The method of claim 10, further comprising providing multiple CDUs and CCUs to one or more additional hardware components.

16. The method of claim 10, further comprising recording an operational history of the CDU, CCU, and the one or more hardware components.

17. A processor comprising one or more logical units to adaptively control an amount of coolant supplied concurrently by each of a coolant distribution unit (CDU) and a cryogenic cooling unit (CCU) to a hardware component, the CDU being operably connected to the hardware component via a first connecting element and the CCU being operably connected to the hardware component via a second connecting element.

18. The processor of claim 17, wherein the one or more logical units comprise a predictive software module to:
retrieve one or more performance metrics of the hardware component; and
determine an activation of the CCU based at least on the performance metrics.

19. The processor of claim 17, wherein the one or more logical units comprise a predictive software module that predicts a need for cryogenic fluid application to the hardware component based at least on one or more historical performance data and one or more performance metrics.

20. The processor of claim 17, further to operate the CDU and CCU based at least on one or more performance metrics including time to first token and output tokens throughput.

21. A data center comprising:
a coolant distribution unit (CDU) operably connected to a hardware component, the CDU to transfer heat from the hardware component via water-based coolant;
a cryogenic cooling unit (CCU) operably connected to the hardware component, the CCU to transfer heat from the hardware component via cryogenic fluid; and
a control system to activate the CDU and the CCU either simultaneously or independently of each other.

22. The data center of claim 21, further comprising thermal insulation between a CDU cooling loop and a CCU cooling loop proximate the hardware component.

23. The data center of claim 21, wherein the hardware component comprises one or more superconducting materials.
